(19) United States
(12) Patent Application Publication
(10) Pub. No.: US 2026/0206438 A1
(43) Pub. Date: Jul. 16, 2026

(54) DISPLAY DEVICE INCLUDING STORAGE CAPACITORS AND ELECTRONIC DEVICE INCLUDING THE SAME

(71) Applicant: SAMSUNG DISPLAY CO., LTD., YONGIN-SI (KR)

(72) Inventors: HYUNGJIN SONG, Yongin-si (KR); SOOJO OCK, Yongin-si (KR); CHAEHAN HYUN, Yongin-si (KR); Daehyun Kim, Yongin-si (KR); SUNG HOON KIM, Yongin-si (KR); HEYJIN SHIN, Yongin-si (KR); Minki Yang, Yongin-si (KR); KWANGSAE LEE, Yongin-si (KR); KEUK-JIN JEONG, Yongin-si (KR)

(21) Appl. No.: 19/383,861

(22) Filed: Nov. 10, 2025

(30) Foreign Application Priority Data
Jan. 13, 2025 (KR) 10-2025-0005015

(51) Int. Cl. H10K 59/131; H10K 59/121

(52) U.S. Cl. CPC H10K 59/131; H10K 59/1213

(57) ABSTRACT

A display device may include a substrate including a first pixel circuit area and a second pixel circuit area adjacent to the first pixel circuit area. The first pixel circuit area may include a first pixel driving circuit part and the second pixel circuit area may include a second pixel driving circuit part. A first conductive pattern and second conductive pattern disposed on the substrate in the first and second pixel circuit areas, respectively. A first power pattern and second power pattern disposed on the first and second conductive patterns in the first and second pixel circuit areas respectively, and at least partially overlapping the first and second conductive patterns, respectively, in a plan view. The first power pattern and the first conductive pattern are parts of a first storage capacitor of the first pixel driving circuit part.

### CROSS-REFERENCE TO RELATED APPLICATION

This U.S. non-provisional patent application claims priority under 35 U.S.C. § 119 to Korean Patent Application No. 10-2025-0005015, filed on January 13, 2025, in the Korean Intellectual Property Office (KIPO), the disclosure of which is incorporated by reference herein in its entirety.

### TECHNICAL FIELD

Embodiments of the present disclosure relate to a display device and, more particularly to, a display device including storage capacitors and an electronic device including the same.

### Discussion of the Related Art

As information technology develops, display devices, which are a communication media between users and information, are gaining widespread demand. Accordingly, the use of display devices such as a liquid crystal display (LCD) device, an organic light emitting display (OLED) device, a plasma display device, and other types of display devices, is on the rise. In some cases, these display devices may experience degraded display quality, and much research is ongoing to rectify the same.

### SUMMARY

Embodiments provide a display device with enhanced display quality. Embodiments provide an electronic device including the display device. Embodiments of the present disclosure relate to a display device including a substrate having an upper surface including a first substrate area adjacent to a second substrate area, and a first pixel driving circuit and a second pixel driving circuit overlapping the first and second substrate areas, respectively. A first conductive structure overlaps the first substrate area; a second conductive structure is disposed in a same layer as the first conductive structure and overlaps the second substrate area; and a first power conductor overlaps each of the first conductive structure and the first substrate area. The first power conductor and the first conductive structure are opposite electrodes of a first storage capacitor of the first pixel driving circuit. A second power conductor is disposed in a same layer as, and spaced from, the first power conductor, and overlaps each of the second substrate area and the second conductive structure. The second power conductor and the second conductive structure are opposite electrodes of a second storage capacitor of the second pixel driving circuit. The display device may further include a power line overlapping and connected to each of the first and second power conductors, where the power line is configured to receive a driving voltage, a first light-emitting element electrically connected to the first pixel driving circuit and configured to emit light having a first color, and a second light-emitting element electrically connected to the second pixel driving circuit and configured to emit light having a second color different from the first color.

In an embodiment, the first power conductor includes a first hole exposing at least a portion of the first conductive structure, and the second power conductor includes a second hole exposing at least a portion of the second conductive structure.

In an embodiment, the display device may further include a first data line disposed on the power line in the first substrate area, and a second data line disposed on the power line in the second substrate area. The first data line and the second data line do not overlap the first power conductor and the second power conductor.

In an embodiment, the first data line and the second data line each at least partially overlap the power line.

In an embodiment, the substrate further includes a third substrate area adjacent to the second substrate area. The display device may further include a third pixel driving circuit overlapping the third substrate area, a third conductive structure disposed on the substrate in the same layer as the first conductive structure in the third substrate area, and a third power conductor disposed on the third conductive structure in the same layer as the first power conductor in the third substrate area, at least partially overlapping the third conductive structure, and spaced apart from the first power conductor. The third power conductor and the third conductive structure are parts of a third storage capacitor of the third pixel driving circuit, and the power line is connected to the third power conductor.

In an embodiment, the display device may further include a third data line disposed on the power line in the third substrate area, where the first data line, the second data line, and the third data line do not overlap the first power conductor, the second power conductor, and the third power conductor, respectively.

In an embodiment, the third power conductor is integrally formed with the second power conductor.

In an embodiment, the third power pattern may be integrally formed with the second power pattern. the third power conductor is spaced apart from the second power conductor.

In an embodiment, the display device may further include a third light-emitting element electrically connected to the third pixel driving circuit part, where the third light-emitting element is configured to emit light having a third color different from the first color and the second color.

In an embodiment, the third power conductor includes a third hole exposing at least a portion of the third conductive structure.

In an embodiment, the display device may further include an additional power line disposed in a same layer as the first data line and the second data line and connected to the power line.

In an embodiment, the display device may further include a lower metal pattern disposed between the substrate and the first conductive structure and the second conductive structure, and at least partially overlapping the first conductive structure and the second conductive structure, where the lower metal pattern is electrically connected to the power line.

In an embodiment, the display device may further include a plurality of lower active patterns, where a first one of the plurality of lower active patterns is disposed in the first substrate area between the substrate and the first conductive structure, and a second one of the plurality of lower active patterns is disposed in the second substrate area and between the substrate and the second conductive structure, and a plurality of first gate electrodes, where a first one of the plurality of first gate electrodes is disposed in the first substrate area on the first one, and a second one of the plurality of first gate electrodes is disposed in the second substrate area on the second one, each of the plurality of first gate electrodes at least partially overlapping a corresponding lower active pattern, where each of the plurality of first gate electrodes and each of the plurality of lower active patterns are parts of a driving transistor of each of the first pixel driving circuit and the second pixel driving circuit, respectively, where the plurality of lower active patterns includes a silicon semiconductor.

In an embodiment, the display device may further include a plurality of upper active patterns, where each of the plurality of upper active patterns is disposed in the first substrate area and the second substrate area on the first power conductor and the second power conductor, respectively, and a plurality of second gate electrodes, where a first one of the plurality of second gate electrodes is disposed in the first substrate area on a corresponding upper active pattern, and a second one of the plurality of second gate electrodes is disposed on another corresponding upper active pattern in the second substrate area, each of the plurality of second gate electrodes at least partially overlapping each of the plurality of upper active patterns, where each of the plurality of second gate electrodes and each of the plurality of upper active patterns are parts of a switching transistor of each of the first pixel driving circuit and the second pixel driving circuit, respectively, where the plurality of upper active patterns includes a metal oxide semiconductor.

An electronic device according to embodiments of the present disclosure include a display device, and a processor for controlling the display device by transmitting input image data and control signal to the display device. The display device may include a substrate having an upper surface including a first substrate area spaced apart from a second substrate area, a first pixel driving circuit and a second pixel driving circuit overlapping the first and second substrate areas, respectively, a first conductive structure overlapping the first substrate area, a second conductive structure disposed in a same layer as the first conductive structure and overlapping the second substrate area, a first power conductor overlapping each of the first conductive structure and the first substrate area, where the first power conductor and the first conductive structure are opposite electrodes of a first storage capacitor of the first pixel driving circuit, a second power conductor disposed in a same layer as, and spaced from, the first power conductor, and overlapping each of the second substrate area and the second conductive structure. The second power conductor and the second conductive structure are opposite electrodes of a second storage capacitor of the second pixel driving circuit. The display device may further include a power line overlapping and connected to each of the first and second power conductors, where the power line is configured to receive a driving voltage, a first light-emitting element electrically connected to the first pixel driving circuit part and configured to emit light having a first color, and a second light-emitting element electrically connected to the second pixel driving circuit and configured to emit light having a second color different from the first color.

In an embodiment, the first power conductor includes a first hole exposing at least a portion of the first conductive structure, and the second power conductor includes a second hole exposing at least a portion of the second conductive structure.

In an embodiment, the display device may further include a first data line disposed in the first substrate area on the power line, and a second data line disposed in the second substrate area on the power line, where the first data line and the second data line do not overlap the first power conductor and the second power conductor.

In an embodiment, the first data line and the second data line each at least partially overlap the power line.

Embodiments of the present disclosure provide an electronic device may include a display device, and a processor for controlling the display device by transmitting input image data and control signal to the display device. The display device may include a substrate having an upper surface including a first substrate area spaced apart from a second substrate area and a third substrate area adjacent to the second substrate area, a first pixel driving circuit, a second pixel driving circuit, and a third pixel driving circuit overlapping the first, second, and third substrate areas, respectively, a first conductive structure overlapping the first substrate area, a second conductive structure disposed in a same layer as the first conductive structure and overlapping the second substrate area, a third conductive structure disposed on the substrate in the same layer as the first conductive structure in the third substrate area, a first power conductor overlapping each of the first conductive structure and the first substrate area, where the first power conductor and the first conductive structure are opposite electrodes of a first storage capacitor of the first pixel driving circuit, a second power conductor disposed in a same layer as, and spaced from, the first power conductor, and overlapping each of the second substrate area and the second conductive structure, where the second power conductor and the second conductive structure are opposite electrodes of a second storage capacitor of the second pixel driving circuit, a third power conductor disposed on the third conductive structure in the same layer as the first power conductor in the third substrate area, at least partially overlapping the third conductive structure, and spaced from the first power conductor, where the third power conductor and the third conductive structure are opposite electrodes of a third storage capacitor of the third pixel driving circuit, a power line overlapping and connected to each of the first and second power conductors, where the power line is configured to receive a driving voltage, a first light-emitting element electrically connected to the first pixel driving circuit and configured to emit light having a first color, and a second light-emitting element electrically connected to the second pixel driving circuit and configured to emit light having a second color different from the first color, and a third light-emitting element electrically connected to the third pixel driving circuit, where the third light-emitting element is configured to emit light having a third color different from the first color and the second color, where the power line is connected to the third power conductor.

In an embodiment, the display device may further include a first data line disposed in the first substrate area on the power line, a second data line disposed in the second substrate area on the power line, and a third data line disposed in the third substrate area on the power line, and where the first data line, the second data line, and the third data line do not overlap the first power conductor, the second power conductor, the third power conductor, respectively.

A display device according to embodiments of the present disclosure may include conductive patterns disposed in each of first, second, and third pixel circuit areas, and corresponding power patterns that form a storage capacitor with the conductive patterns in each of the first, second, and third pixel circuit areas. A driving voltage may be applied to the power patterns. In addition, data lines which receives a data voltage might not overlap the power patterns in a plan view. Accordingly, the formation of parasitic capacitor between each of the data lines and each of the power patterns may be minimized or reduced. In some cases, the crosstalk phenomenon caused by the formation of the parasitic capacitance may be prevented or reduced.

### BRIEF DESCRIPTION OF THE DRAWINGS

FIG. 1 is a plan view illustrating a display device according to embodiments of the present disclosure.

FIG. 2 is a block diagram schematically illustrating the display device of FIG. 1.

FIG. 3 is a circuit diagram illustrating a circuit structure of one pixel of FIGS. 1 and 2.

FIG. 4 is a cross-sectional view illustrating a display panel of FIGS. 1 and 2.

FIGS. 5, 6, 7, 8, 9, 10, 11, 12, 13, 14, 15, 16, 17, 18, and 19 are layout views illustrating components of a circuit layer of FIG. 4.

FIG. 20 is a cross-sectional view taken along line I-I’ of FIG. 19.

FIG. 21 is a layout view illustrating an example of a second gate conductive layer of FIG. 10.

FIG. 22 is a block diagram illustrating an electronic device according to embodiments of the present disclosure.

FIG. 23 is a schematic view showing an electronic device according to various embodiments.

### DETAILED DESCRIPTION

Hereinafter, embodiments of the present disclosure are explained in detail with reference to the accompanying drawings. In the following embodiments, it is to be understood that the terms such as "including" and "having" are intended to indicate the existence of the features, or elements disclosed in the disclosure, and are not necessarily intended to preclude the possibility that one or more other features or elements may exist or may be added.

It will be understood that when a layer, region, or element is referred to as being formed on another layer, region, or element, the layer, region, or element can be directly or indirectly formed on the other layer, region, or element. For example, intervening layers, regions, or elements may be present between the layers, regions, or elements, respectively.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Herein, the term “pattern”, in the context of a circuit element or elements, may refer to a structure of the circuit element (such as a conductive line or patch) or to an arrangement of a plurality of circuit elements. For example, a “power pattern” may refer to a conductive structure that provides power to another circuit element. The term “overlapping” may be used to encompass both a complete overlapping and a partial overlapping between two elements in a plan view.

As used herein, the term “a first pixel circuit area” may be referred to as “a first substrate area”. The term “a second pixel circuit area” may be referred to as “a second substrate area”. The term “a third pixel circuit area” may be referred to as “a third substrate area”. The term “a first pixel driving circuit part” may be referred to as “a first pixel driving circuit”. The term “a second pixel driving circuit part” may be referred to as “a second pixel driving circuit”. The term “a third pixel driving circuit part” may be referred to as “a third pixel driving circuit”. The term “a first conductive pattern” may be referred to as “a first conductive structure”. The term “a second conductive pattern” may be referred to as “a second conductive structure”. The term “a first power pattern” may be referred to as “a first power conductor”. The term “a second power pattern” may be referred to as “a second power conductor”. The term “a first power line” may be referred to as “a power line”. The term “a second power line” may be referred to as “an additional power line”.

Embodiments of the inventive concept may optimize the layout of driving circuits, storage capacitors, and conductive patterns within a display device to reduce parasitic effects and enhance display uniformity and image quality. Embodiments provide a display device having a multilayer pixel circuit structure for enhancing electrical isolation and reducing parasitic capacitance in display panels. The display device may include a substrate having a first pixel circuit area and a second pixel circuit area arranged in a first direction, each including a pixel driving circuit. A conductive pattern is formed in each pixel circuit area, and a corresponding power pattern is disposed on the conductive pattern on a separate layer. The conductive pattern and the power pattern form a storage capacitor and partially overlaps each other in a plan view. A power line is disposed on the power patterns and electrically connected to the conductive pattern to supply a driving voltage. A first data line and a second data line extend in a second direction, crossing the first direction, and are arranged on the power line while being spatially separated from the power patterns in a plan view. This configuration enables the reduction of parasitic capacitance between the data lines and power patterns.

In some embodiments, the display device further may include a plurality of lower active patterns and first gate electrodes in the first and second pixel circuit areas, which form the driving transistors. An upper active pattern and second gate electrodes are further disposed to form switching transistors. The lower active patterns may include silicon semiconductors, and the upper active patterns may include metal oxide semiconductors. In an embodiment, a lower metal pattern may be disposed between the substrate and the conductive patterns and electrically connected to the power line, providing enhanced electrical shielding and supporting multilayer routing. This stacked architecture, including a plurality of capacitor holes in the power patterns, enables efficient spatial isolation of signal layers.

By structurally separating the conductive patterns, power patterns, and signal lines into distinct layers while maintaining electrical connectivity via vertical holes, the display device minimizes crosstalk. In some cases, the power patterns may be formed independently or integrally connected to structures across adjacent pixel circuit areas.

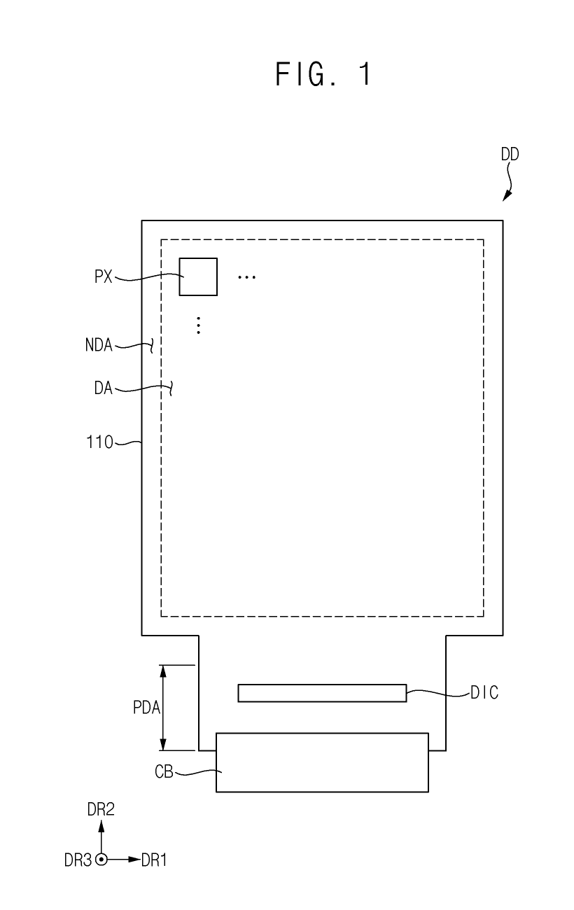

FIG. 1 is a plan view illustrating a display device according to embodiments of the present disclosure.

Referring to FIG. 1, a display device DD may include a display panel 110, a driving integrated circuit DIC, and a circuit board CB.

The display device DD may have a rectangular planar shape (e.g., a rectangular planar shape with rounded corners). However, embodiments of the present disclosure are not necessarily limited thereto, and the display device DD may have various planar shapes. For example, the planar shape may be a square, circular, or polygonal shape based on design requirements or device integration constraints.

The display panel 110 may include a display area DA and a non-display area NDA. The display area DA may be an area capable of displaying an image (e.g., still image) or a video (e.g., moving image) by generating light or by controlling the transmittance of light from an external light source. The non-display area NDA may be an area that does not display an image. The non-display area NDA may be located around the display area DA. For example, the non-display area NDA may entirely surround the display area DA. In some cases, the non-display area NDA may also include peripheral circuitry such as gate drivers, data lines, and pads for interfacing with external components.

The display panel 110 may include a plurality of pixels PX arranged in the display area DA. The pixels PX may be arranged in a matrix form along a first direction DR1 and a second direction DR2 crossing the first direction DR1. However, embodiments of the present disclosure are not necessarily limited thereto, and the pixels PX may be arranged in various forms.

Each of the pixels PX may include a driving element (e.g., a driving thin-film transistor) for generating a driving current and a light-emitting element electrically connected to the driving element and which generates light based on the driving current. Accordingly, the pixels PX may emit light according to the driving current. By emitting light from the pixels PX, the display area DA may display an image. In an embodiment, the driving element may be part of a pixel driving circuit including one or more transistors and capacitors configured to control the timing and magnitude of the driving current.

Lines connected to the pixels PX may be further disposed in the display area DA. For example, the lines may include data lines, gate signal lines, emission control lines, or other lines for voltage supply and signal timing.

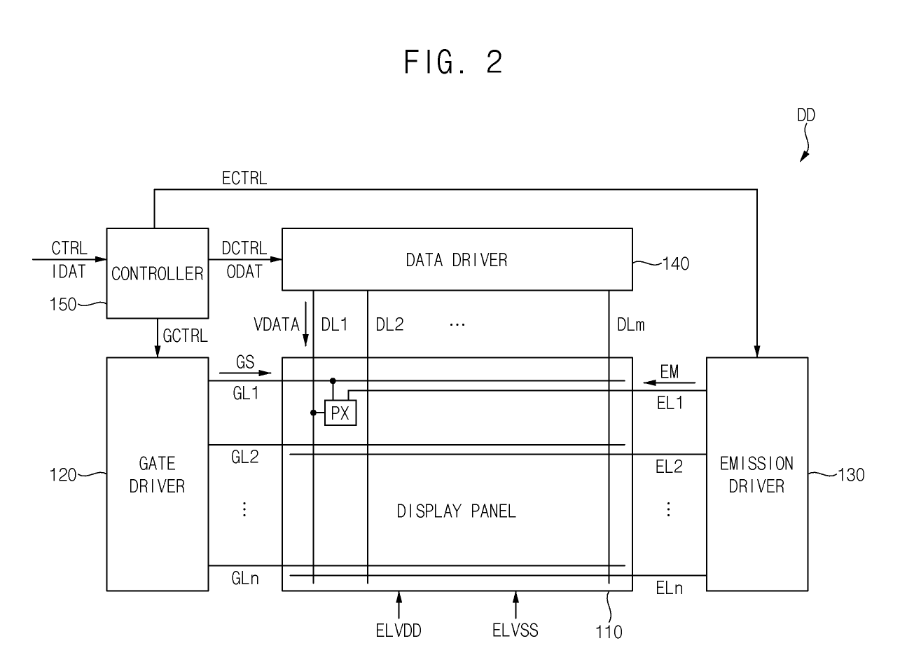

Drivers for driving the pixels PX may be disposed in the non-display area NDA. For example, the drivers may include a gate driver (e.g., gate driver 120 in FIG. 2) and an emission driver (e.g., emission driver 130 in FIG. 2). The pixels PX may emit light based on signals received from the drivers.

The non-display area NDA may include a pad area PDA. The pad area PDA may be located at one side of the display area DA. The pad area PDA may extend in the first direction DR1.

The driving integrated circuit DIC may be bonded to the pad area PDA of the display panel 110. Accordingly, the driving integrated circuit DIC may be electrically connected to the display panel 110.

The driving integrated circuit DIC may convert a digital data signal among driving signals into an analog data signal and provide the analog data signal to the pixels PX. For example, the driving integrated circuit DIC may be a data driver (e.g., data driver 140 in FIG. 2).

The circuit board CB may be bonded to one end of the pad area PDA on the display panel 110. Accordingly, the circuit board CB may be electrically connected to the display panel 110. The other end of the circuit board CB may be electrically connected to an external device. Signals, voltages, and/or control commands/data generated from the external device may be provided to the driving integrated circuit DIC and the pixels PX through the circuit board CB.

For example, the circuit board CB may be a flexible printed circuit board (FPCB), a printed circuit board (PCB), or a flexible flat cable (FFC).

In FIG. 1, the driving integrated circuit DIC is illustrated as being disposed by a chip on plastic (COP) method or a chip on glass (COG) method. However, embodiments of the present disclosure are not necessarily limited thereto. For example, the driving integrated circuit DIC may be disposed by a chip on film (COF) method.

FIG. 2 is a block diagram schematically illustrating the display device of FIG. 1.

Referring to FIG. 2, a display device DD may include a display panel 110, a gate driver 120, an emission driver 130, a data driver 140, and a controller 150.

The display panel 110 may include a plurality of gate lines GL1 to GLn, a plurality of data lines DL1 to DLm, a plurality of emission control lines EL1 to ELn, and a plurality of pixels PX (where n and m are integers of 2 or more). The gate lines GL1 to GLn, the emission control lines EL1 to ELn, and the data lines DL1 to DLm may be electrically connected to the pixels PX. The gate lines GL1 to GLn may receive gate signals GS, the emission control lines EL1 to ELn may receive emission control signals EM, and the data lines DL1 to DLm may receive data voltages VDATA. The signal lines may extend across the display area in respective directions and intersect at pixel positions to enable selective addressing and activation of the pixels PX.

Each of the gate lines GL1 to GLn may extend in a first direction (e.g., row direction). Each of the emission control lines EL1 to ELn may extend in the first direction. Each of the data lines DL1 to DLm may extend in a second direction (e.g., column direction) crossing the first direction. The gate lines GL1 to GLn, the emission control lines EL1 to ELn, and the data lines DL1 to DLm may be insulated from each other. The pixels PX may be arranged in areas where the gate lines GL1 to GLn (or the emission control lines EL1 to ELn) intersect the data lines DL1 to DLm.

In an embodiment, each of the pixels PX may include a switching transistor which provides the data voltage VDATA in response to the gate signal GS, a storage capacitor which stores the data voltage VDATA provided by the switching transistor, a driving transistor which generates a driving current based on the data voltage VDATA stored in the storage capacitor, and a light-emitting element which emits light based on the driving current generated by the driving transistor. For example, the light-emitting element may include a light-emitting diode (LED), an organic light-emitting diode (OLED), or a quantum dot (QD) light-emitting element.

The pixels PX may receive a driving voltage ELVDD and a common voltage ELVSS. The pixels PX may receive the data voltage VDATA in response to the gate signal GS and the emission control signal EM, and may generate light of a gray level corresponding to the data voltage VDATA using the driving voltage ELVDD and the common voltage ELVSS. In some cases, the driving voltage ELVDD and the common voltage ELVSS may be supplied to the display panel 110 and pixels PX through corresponding power lines.

The gate driver 120 may provide the gate signals GS to the pixels PX through the gate lines GL1 to GLn based on a gate control signal GCTRL received from the controller 150. In an embodiment, the gate driver 120 may sequentially provide the gate signals GS to the pixels PX in units of rows. The gate control signal GCTRL may include a gate start signal, a gate clock signal, or other timing signals for row scanning operations. However, embodiments of the present disclosure are not necessarily limited thereto. For example, the gate driver 120 may be integrated or formed in a peripheral portion of the display panel 110. Alternatively, the gate driver 120 may be implemented using one or more integrated circuits (IC).

The emission driver 130 may provide the emission control signals EM to the pixels PX through the emission control lines EL1 to ELn based on the emission control signal ECTRL received from the controller 150. In an embodiment, the emission driver 130 may sequentially provide the emission control signals EM to the pixels PX in units of rows. The emission control signal ECTRL may include an emission start signal, an emission clock signal, or additional synchronization signals for controlling the light emission period of the pixels. However, embodiments of the present disclosure are not necessarily limited thereto. For example, the emission driver 130 may be integrated or formed in a peripheral portion of the display panel 110. Alternatively, the emission driver 130 may be implemented using one or more integrated circuits (IC).

The data driver 140 may receive a data control signal DCTRL and an output image data ODAT from the controller 150, and may provide data voltages VDATA to the pixels PX through the data lines DL1 to DLm based on the data control signal DCTRL and the output image data ODAT. The data control signal DCTRL may include an output data enable signal, a horizontal start signal, a load signal, or other scanning and signal commands. However, embodiments of the present disclosure are not necessarily limited thereto. For example, the data driver 140 may be implemented as a single integrated circuit, and the integrated circuit may be referred to as a timing controller embedded data driver (TED). Alternatively, the data driver 140 may be implemented using separate integrated circuits.

The controller 150 may receive an input image data IDAT and a control signal CTRL from an external host processor. For example, the controller 150 may be a timing controller, and the host processor may be an application processor (AP), a graphic processing unit (GPU), or a graphic card. In an embodiment, the input image data IDAT may be RGB image data including red image data, green image data, and blue image data. The control signals CTRL may include a vertical sync signal, a horizontal sync signal, an input data enable signal, a master clock signal, or other timing and control signals associated with image frame synchronization. However, embodiments of the present disclosure are not necessarily limited thereto.

The controller 150 may generate the gate control signal GCTRL, the emission control signal ECTRL, the data control signal DCTRL, and the output image data ODAT based on the input image data IDAT and the control signals CTRL. The controller 150 may provide the gate control signal GCTRL to the gate driver 120 to control the operation of the gate driver 120, may provide the emission control signal ECTRL to the emission driver 130 to control the operation of the emission driver 130, and may provide the output image data ODAT and the data control signal DCTRL to the data driver 140 to control the operation of the data driver 140. The controller 150 may synchronize these signals to ensure accurate timing across the rows and columns of the display panel 110.

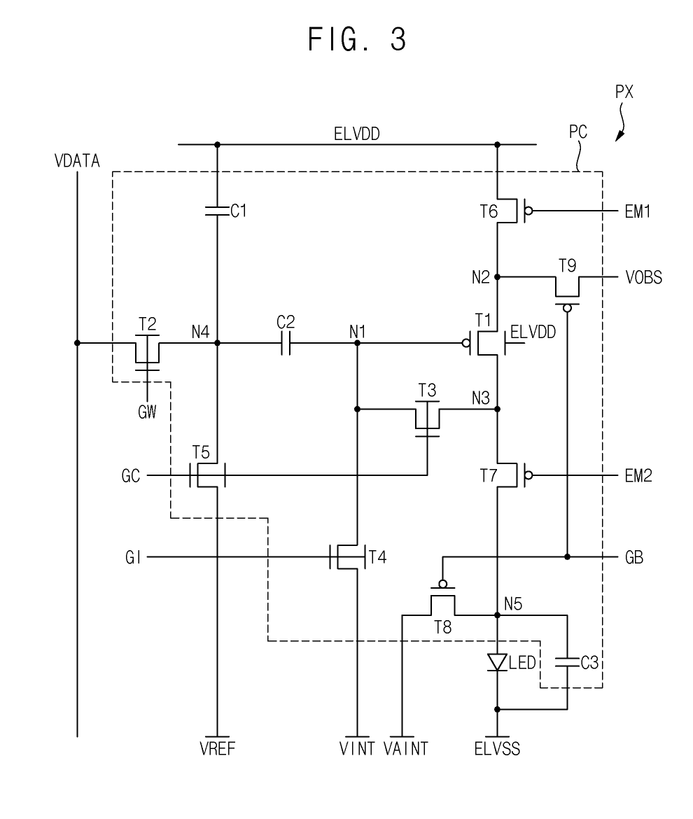

FIG. 3 is a circuit diagram illustrating a circuit structure of one pixel of FIGS. 1 and 2.

Referring to FIG. 3, each pixel PX may include a pixel driving circuit part PC and a light-emitting element LED electrically connected to the pixel driving circuit part PC. The pixel driving circuit part PC may generate a driving current, and the light-emitting element LED may generate light (or emit light) based on the driving current. The pixel driving circuit part PC may control the light emission based on input signals including data voltage, gate signals, and emission control signals.

In an embodiment, the pixel driving circuit part PC may include a plurality of transistors including a first transistor T1, a second transistor T2, a third transistor T3, a fourth transistor T4, a fifth transistor T5, a sixth transistor T6, a seventh transistor T7, an eighth transistor T8, and a ninth transistor T9. In one aspect, the pixel driving circuit part PC may include a plurality of capacitors including a first capacitor C1, a second capacitor C2, and a third capacitor C3. Each transistor and capacitor may be configured to perform signal processing, initialization, or current driving within the pixel PX.

In one embodiment, the first transistor T1, the sixth transistor T6, the seventh transistor T7, the eighth transistor T8, and the ninth transistor T9 may be PMOS transistors, and the second transistor T2, the third transistor T3, the fourth transistor T4, and the fifth transistor T5 may be NMOS transistors. However, embodiments of the present disclosure are not necessarily limited thereto.

If the pixel driving circuit part PC may include an NMOS transistor and a PMOS transistor, an active pattern of the NMOS transistor may include an oxide semiconductor, and an active pattern of the PMOS transistor may include a silicon semiconductor. However, embodiments of the present disclosure are not necessarily limited thereto, and the active pattern of the NMOS transistor may include a silicon semiconductor, and the active pattern of the PMOS transistor may include an oxide semiconductor.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide the driving current to the light-emitting element LED. The first transistor T1 may further include a back gate electrode configured to receive a driving voltage ELVDD.

The second transistor T2 may include a gate electrode, a first electrode, and a second electrode. The gate electrode of the second transistor T2 may receive a first gate signal GW. The first electrode of the second transistor T2 may be connected to a fourth node N4. The second electrode of the second transistor T2 may receive the data voltage VDATA. The second transistor T2 may further include a back gate electrode connected to the gate electrode and configured to receive the first gate signal GW.

The second transistor T2 may be turned on or off in response to the first gate signal GW. For example, if the first gate signal GW has an activation level, the second transistor T2 may be turned on. In this case, the second transistor T2 may provide the data voltage VDATA to the fourth node N4. Conversely, if the first gate signal GW has an inactivation level, the second transistor T2 may be turned off. In this case, the second transistor T2 may block the supply of the data voltage VDATA.

The third transistor T3 may include a gate electrode, a first electrode, and a second electrode. The gate electrode of the third transistor T3 may receive a second gate signal GC. The first electrode of the third transistor T3 may be connected to the third node N3. The second electrode of the third transistor T3 may be connected between the first node N1 and the fourth transistor T4. The third transistor T3 may further include a back gate electrode connected to the gate electrode and configured to receive the second gate signal GC. In one aspect, the third node N3 may also be connected to an electrode of the first transistor T1, such that the first electrode of the third transistor T3 is electrically connected to the first transistor T1 via the third node N3.

The third transistor T3 may be turned on or off in response to the second gate signal GC. For example, if the second gate signal GC has an activation level, the third transistor T3 may be turned on. In some cases, the third transistor T3 may diode-connect the first transistor T1. For example, the third transistor T3 may compensate for the threshold voltage of the first transistor T1. Conversely, if the second gate signal GC has an inactivation level, the third transistor T3 may be turned off. In some cases, the first transistor T1 might not be diode-connected. For example, the first transistor T1 may operate independently of diode connection.

The fourth transistor T4 may include a gate electrode, a first electrode, and a second electrode. The gate electrode of the fourth transistor T4 may receive a third gate signal GI. The first electrode of the fourth transistor T4 may be connected to the second electrode of the third transistor T3. The second electrode of the fourth transistor T4 may receive an initialization voltage VINT. The fourth transistor T4 may further include a back gate electrode connected to the gate electrode configured to receive the third gate signal GI. In one aspect, the first electrode of the fourth transistor T4 may be connected to the second electrode of the third transistor T3 and the gate electrode of T1 via node 1 N1.

The fourth transistor T4 may be turned on or off in response to the third gate signal GI. For example, if the third gate signal GI has an activation level, the fourth transistor T4 may be turned on. In some cases, the fourth transistor T4 may provide the initialization voltage VINT to the second electrode of the third transistor T3. Conversely, if the third gate signal GI has an inactivation level, the fourth transistor T4 may be turned off. In some cases, the fourth transistor T4 may block the supply of the initialization voltage VINT.

The fifth transistor T5 may include a gate electrode, a first electrode, and a second electrode. The gate electrode of the fifth transistor T5 may receive the second gate signal GC. The first electrode of the fifth transistor T5 may be connected to the fourth node N4. The second electrode of the fifth transistor T5 may receive a reference voltage VREF. The fifth transistor T5 may further include a back gate electrode connected to the gate electrode and configured to receive the second gate signal GC.

A gate signal line connected to the gate electrode of the third transistor T3 and a gate signal line connected to the gate electrode of the fifth transistor T5 may be independent of each other. However, embodiments of the present disclosure are not necessarily limited thereto, and a single gate signal line which receives the second gate signal GC may be connected to the gate electrode of the third transistor T3 and the gate electrode of the fifth transistor T5.

The fifth transistor T5 may be turned on or off in response to the second gate signal GC. For example, if the second gate signal GC has an activation level, the fifth transistor T5 may be turned on. In some cases, the fifth transistor T5 may provide the reference voltage VREF to the fourth node N4. Conversely, if the second gate signal GC has an inactivation level, the fifth transistor T5 may be turned off. In some cases, the fifth transistor T5 may block the supply of the reference voltage VREF.

The sixth transistor T6 may include a gate electrode, a first electrode, and a second electrode. The gate electrode of the sixth transistor T6 may receive a first emission control signal EM1. The first electrode of the sixth transistor T6 may receive the driving voltage ELVDD. The second electrode of the sixth transistor T6 may be connected to the second node N2. The second node N2 may also be connected to the first electrode of the first transistor T1 and the second electrode of the sixth transistor T6.

The sixth transistor T6 may be turned on or off in response to the first emission control signal EM1. For example, if the first emission control signal EM1 has an activation level, the sixth transistor T6 may be turned on. In some cases, the sixth transistor T6 may provide the driving voltage ELVDD to the first transistor T1. Conversely, if the first emission control signal EM1 has an inactivation level, the sixth transistor T6 may be turned off. In some cases, the sixth transistor T6 may block the supply of the driving voltage ELVDD.

The seventh transistor T7 may include a gate electrode, a first electrode, and a second electrode. The gate electrode of the seventh transistor T7 may receive a second emission control signal EM2. The first electrode of the seventh transistor T7 may be connected to the third node N3. The second electrode of the seventh transistor T7 may be connected to a fifth node N5. The third node N3 may also be connected to the second electrode of the first transistor T1, such that the seventh transistor T7 receives a driving current from the first transistor T1.

An emission control line connected to the gate electrode of the sixth transistor T6 and an emission control line connected to the gate electrode of the seventh transistor T7 may be independent of each other. However, embodiments of the present disclosure are not necessarily limited thereto, and a single emission control line may be connected to the gate electrode of the sixth transistor T6 and the gate electrode of the seventh transistor T7. In such case, the first emission control signal EM1 may be the same as the second emission control signal EM2.

The seventh transistor T7 may be turned on or off in response to the second emission control signal EM2. For example, if the second emission control signal EM2 has an activation level, the seventh transistor T7 may be turned on. In some cases, the seventh transistor T7 may provide the driving current generated by the first transistor T1 to the fifth node N5. Conversely, if the second emission control signal EM2 has an inactivation level, the seventh transistor T7 may be turned off. In some cases, the seventh transistor T7 may block the supply of the driving current generated by the first transistor T1.

The eighth transistor T8 may include a gate electrode, a first electrode, and a second electrode. The gate electrode of the eighth transistor T8 may receive a fourth gate signal GB. The first electrode of the eighth transistor T8 may receive an anode initialization voltage VAINT. The second electrode of the eighth transistor T8 may be connected to the fifth node N5. In one aspect, the fifth node N5 may serve as a connection node to the anode of the light-emitting element LED.

The eighth transistor T8 may be turned on or off in response to the fourth gate signal GB. For example, if the fourth gate signal GB has an activation level, the eighth transistor T8 may be turned on. In some cases, the eighth transistor T8 may provide the anode initialization voltage VAINT to the fifth node N5. Conversely, if the fourth gate signal GB has an inactivation level, the eighth transistor T8 may be turned off. In some cases, the eighth transistor T8 may block the supply of the anode initialization voltage VAINT.

The ninth transistor T9 may include a gate electrode, a first electrode, and a second electrode. The gate electrode of the ninth transistor T9 may receive the fourth gate signal GB. The first electrode of the ninth transistor T9 may receive a bias voltage VOBS. The second electrode of the ninth transistor T9 may be connected to the second node N2. The second node N2 may also be connected to the first electrode of the first transistor T1, such that the ninth transistor T9 is capable of injecting the bias voltage VOBS into the driving current path to the first transistor T1.

A single gate signal line which receives the fourth gate signal GB may be connected to the gate electrode of the eighth transistor T8 and the gate electrode of the ninth transistor T9. However, embodiments of the present disclosure are not necessarily limited thereto, and a gate signal line connected to the gate electrode of the eighth transistor T8 and a gate signal line connected to the gate electrode of the ninth transistor T9 may be independent of each other.

The ninth transistor T9 may be turned on or off in response to the fourth gate signal GB. For example, if the fourth gate signal GB has an activation level, the ninth transistor T9 may be turned on. In some cases, the ninth transistor T9 may provide the bias voltage VOBS to the second node N2. Conversely, if the fourth gate signal GB has an inactivation level, the ninth transistor T9 may be turned off. In some cases, the ninth transistor T9 may block the supply of the bias voltage VOBS.

In an embodiment, the first electrode of each of the first transistor T1, the second transistor T2, the third transistor T3, the fourth transistor T4, the fifth transistor T5, the sixth transistor T6, the seventh transistor T7, the eighth transistor T8, and the ninth transistor T9 may be a source electrode, and the second electrode may be a drain electrode. However, the embodiments of the present disclosure are not necessarily limited thereto. Embodiments of the present disclosure are not necessarily limited to this configuration or to the number of transistors described above. For example, other embodiments may include fewer than nine transistors or more than nine transistors, based on the design requirements of the pixel driving circuit.

The first capacitor C1 may include a first electrode and a second electrode. The first electrode of the first capacitor C1 may receive the driving voltage ELVDD. The second electrode of the first capacitor C1 may be connected to the fourth node N4. For example, the first capacitor C1 may be connected between the driving voltage ELVDD and the fourth node N4.

The second capacitor C2 may include a first electrode and a second electrode. The first electrode of the second capacitor C2 may be connected to the fourth node N4. The second electrode of the second capacitor C2 may be connected to the first node N1. Accordingly, the second capacitor C2 may store a voltage corresponding to a potential difference between the data voltage and a gate voltage of the first transistor T1.

The third capacitor C3 may include a first electrode and a second electrode. The first electrode of the third capacitor C3 may be connected to the fifth node N5. The second electrode of the third capacitor C3 may be connected to a cathode electrode of the light-emitting element LED. In some embodiments, the third capacitor C3 might not be formed between the fifth node N5 and the cathode electrode.

The light-emitting element LED may include an anode electrode and the cathode electrode. The anode electrode of the light-emitting element LED may be connected to the fifth node N5. The cathode electrode of the light-emitting element LED may receive the common voltage ELVSS. The common voltage ELVSS may have a voltage level lower than a voltage level of the driving voltage ELVDD.

In FIG. 3, one pixel driving circuit part PC is illustrated as including nine transistors and three capacitors. However, embodiments of the present disclosure are not necessarily limited thereto. For example, the pixel driving circuit part may include fewer or more than nine transistors and/or fewer or more than three capacitors based on a target functionality, performance, or circuit complexity.

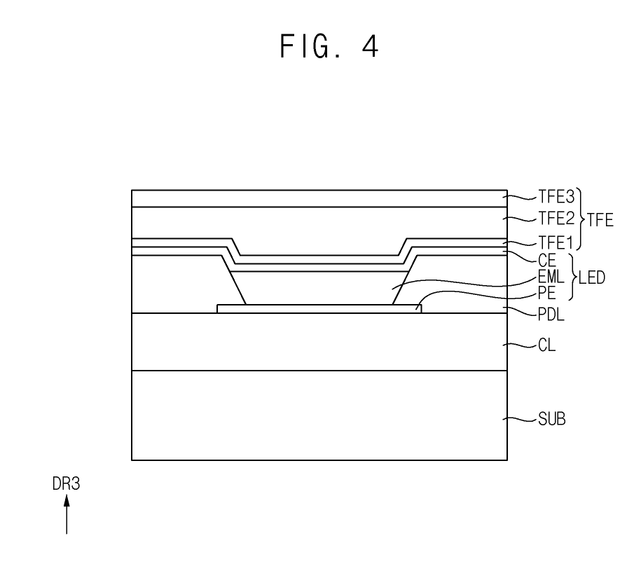

FIG. 4 is a cross-sectional view illustrating a display panel of FIGS. 1 and 2. The cross-section corresponds to a region including the light-emitting element and corresponding layers disposed on a substrate SUB.

Referring to FIG. 4, the display panel 110 may include a substrate SUB, a circuit layer CL, a light-emitting element LED, a pixel defining layer PDL, and an encapsulation layer TFE. In one aspect, the light-emitting element LED may include a pixel electrode PE, a light-emitting layer EML, and a common electrode CE. In one aspect, the encapsulation layer TFE may include a first inorganic layer TFE1, an organic layer TFE2, and a second inorganic layer TFE3.

The substrate SUB may include a transparent material or an opaque material. The substrate SUB may be formed of a transparent resin substrate. Examples of the transparent resin substrate may include a polyimide substrate and other substrates. In some cases, the polyimide substrate may include a first organic layer, a first barrier layer, a second organic layer, or other multi-layer configurations. In some embodiments, the substrate SUB may include a quartz substrate, a synthetic quartz substrate, a calcium fluoride substrate, an F-doped quartz substrate, a soda-lime glass substrate, a non-alkali glass substrate, or other insulating substrates. These substrates may be used alone or in combination with each other. In some cases, the substrate has an upper surface including a first substrate area adjacent to a second substrate area.

The circuit layer CL may be disposed on the upper surface of the substrate SUB. The circuit layer CL may provide signals and voltages for light emission to the light-emitting element LED. For example, the circuit layer CL may include the pixel driving circuit part PC of FIG. 3.

A pixel electrode PE may be disposed on the circuit layer CL. The pixel electrode PE may receive the signals and voltages from the circuit layer CL. For example, the pixel electrode PE may include a metal, an alloy, a metal nitride, a conductive metal oxide, or a transparent conductive material. For example, the pixel electrode PE may serve as an anode electrode.

The pixel define layer PDL may be disposed on the circuit layer CL and the pixel electrode PE. The pixel defining layer PDL may define an opening exposing at least a portion of the pixel electrode PE. By defining the opening, the pixel defining layer PDL may define each of the pixels PX which emits light. The pixel defining layer PDL may include an organic material and/or an inorganic material. Examples of the organic material which can be used as the pixel defining layer PDL may include photoresist, polyacrylic resin, polyimide resin, polyamide resin, siloxane resin, acrylic resin, epoxy resin, or other polymeric insulators. These materials may be used alone or in combination with each other.

A light-emitting layer EML may be disposed on the pixel electrode PE. For example, the light-emitting layer EML may be disposed in the opening of the pixel defining layer PDL. The light-emitting layer EML may include a light-emitting material for emitting light. For example, the light-emitting layer EML may include an organic light-emitting material or an inorganic light-emitting material.

The common electrode CE may be disposed on the pixel defining layer PDL and the light-emitting layer EML. For example, the common electrode CE may include a metal, an alloy, a metal nitride, a conductive metal oxide, or a transparent conductive material. These materials may be used alone or in combination with each other. For example, the common electrode CE may serve as a cathode electrode.

Accordingly, the light-emitting element LED including the pixel electrode PE, the light-emitting layer EML, and the common electrode CE may be disposed on the substrate SUB. The pixel driving circuit part PC and the light-emitting element LED may form one pixel PX.

The encapsulation layer TFE may be disposed on the common electrode CE. The encapsulation layer TFE may protect the light-emitting element LED from external oxygen and moisture. The encapsulation layer TFE may include at least one inorganic layer and at least one organic layer. For example, the encapsulation layer TFE may include a first inorganic layer TFE1 disposed on the common electrode CE, an organic layer TFE2 disposed on the first inorganic layer TFE1, and a second inorganic layer TFE3 disposed on the organic layer TFE2. In some embodiments, the encapsulation layer TFE may be formed as a single-layer structure or may include two or more layers stacked on one another, based on a target moisture and oxygen barrier performance.

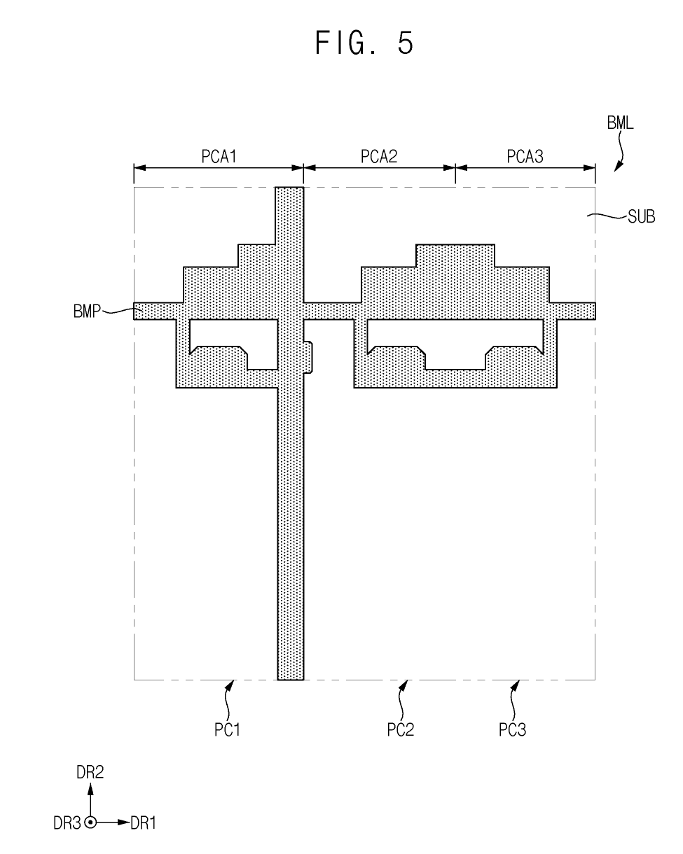

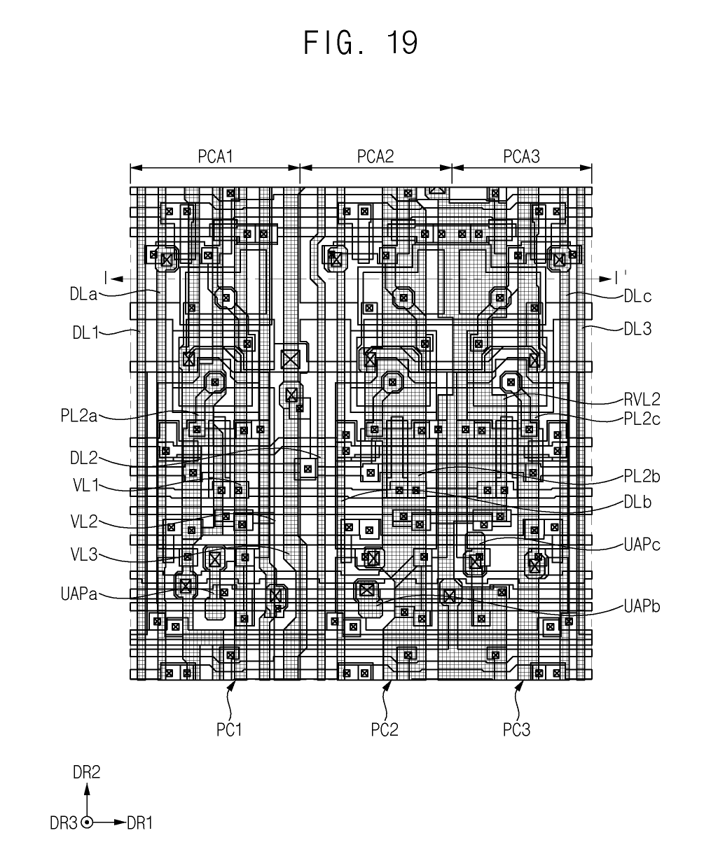

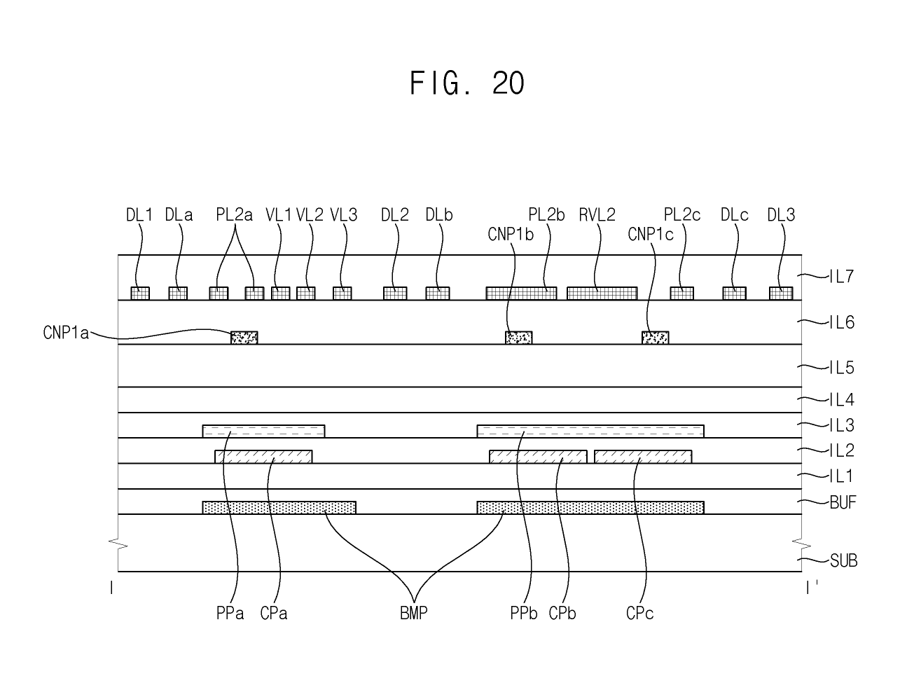

FIGS. 5 to 19 are layout views illustrating components of a circuit layer of FIG. 4. FIG. 20 is a cross-sectional view taken along line I-I’ of FIG. 19. The light-emitting element LED of FIG. 4 may be disposed on the layout view illustrated in FIG. 19.

Referring to FIGS. 1, 2, and 5, the substrate SUB may include a plurality of pixel circuit areas. For example, the pixel circuit areas may be disposed in a matrix form along the first direction DR1 and the second direction DR2. The pixel circuit areas may include a first pixel circuit area PCA1, a second pixel circuit area PCA2, and a third pixel circuit area PCA3.

The second pixel circuit area PCA2 may be adjacent to the first pixel circuit area PCA1 in the first direction DR1, and the third pixel circuit area PCA3 may be adjacent to the second pixel circuit area PCA2 in the first direction DR1. For example, the second pixel circuit area PCA2 may be located between the first pixel circuit area PCA1 and the third pixel circuit area PCA3 in a plan view. Each pixel circuit area may correspond to one pixel PX and include a corresponding pixel driving circuit part.

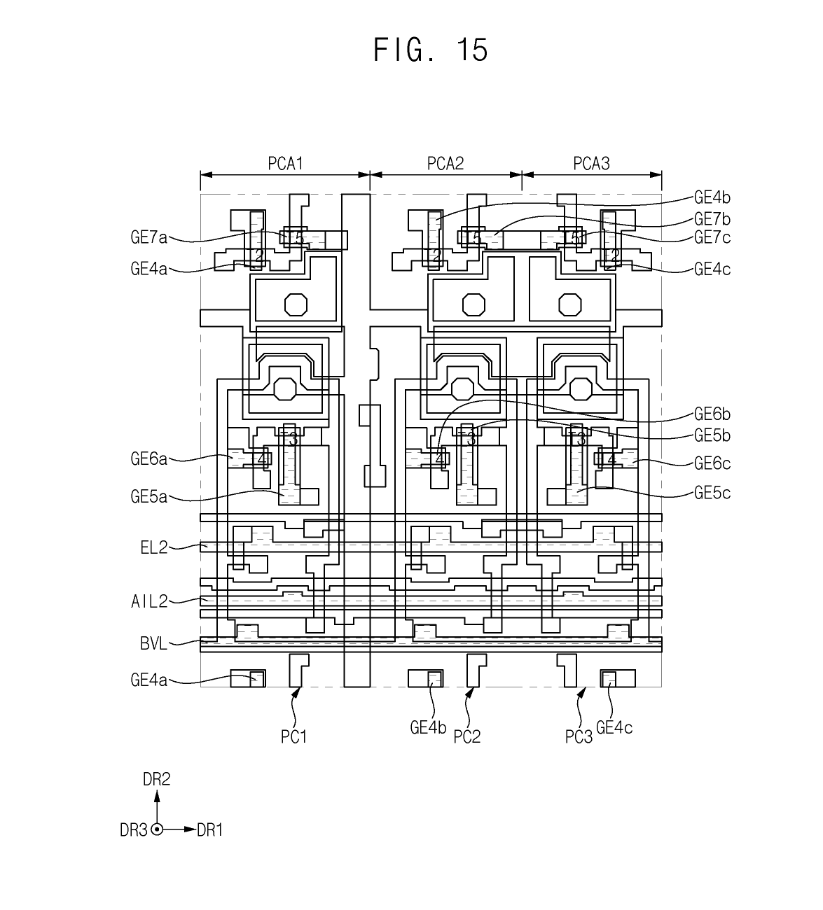

The circuit layer CL may include a first pixel driving circuit part (e.g., PC1 in FIG. 15) disposed in the first pixel circuit area PCA1, a second pixel driving circuit part (e.g., PC2 in FIG. 15) disposed in the second pixel circuit area PCA2, and a third pixel driving circuit part (e.g., PC3 in FIG. 15) disposed in the third pixel circuit area PCA3. The third pixel driving circuit part may have a structure in which the second pixel driving circuit part is symmetrical with respect to a virtual line extending in the second direction DR2.

Each of the first pixel driving circuit part, the second pixel driving circuit part, and the third pixel driving circuit part may correspond to the pixel driving circuit part PC of FIG. 3. For example, each of the first, second, and third pixel driving circuit parts may include nine transistors and three capacitors. The internal circuit configuration of each pixel driving circuit part may be the substantially the same based on the position relative to the virtual line.

The first pixel driving circuit part may be electrically connected to a first light-emitting element, the second pixel driving circuit part may be electrically connected to a second light-emitting element, and the third pixel driving circuit part may be electrically connected to a third light emitting element. The first, second, and third light-emitting elements may emit light of different colors. For example, the first light-emitting element may emit green light (or blue light), the second light-emitting element may emit red light, and the third light emitting element may emit blue light (or green light). However, the embodiments of the present disclosure are not necessarily limited thereto. For example, other color arrangements may also be used. The first, second, and third light-emitting elements may correspond to the light-emitting element LED of FIGS. 3 and 4.

Hereinafter, components of the first pixel driving circuit part, the second pixel driving circuit part, and the third pixel driving circuit part are described.

The circuit layer CL may include a lower metal layer BML disposed on the substrate SUB.

The lower metal layer BML may include a lower metal pattern BMP. The lower metal pattern BMP may be disposed to extend continuously across the first, second, and third pixel circuit areas PCA1, PCA2, and PCA3. For example, the lower metal pattern BMP may include a first portion extending in a first direction DR1 and a second portion extending in a second direction DR2. In addition, the lower metal pattern BMP may receive a driving voltage (e.g., ELVDD of FIG. 3).

For example, the lower metal layer BML may include a metal, an alloy, a metal nitride, a conductive metal oxide, or a transparent conductive material such as indium tin oxide (ITO) or indium zinc oxide (IZO). These materials may be used alone or in combination with each other.

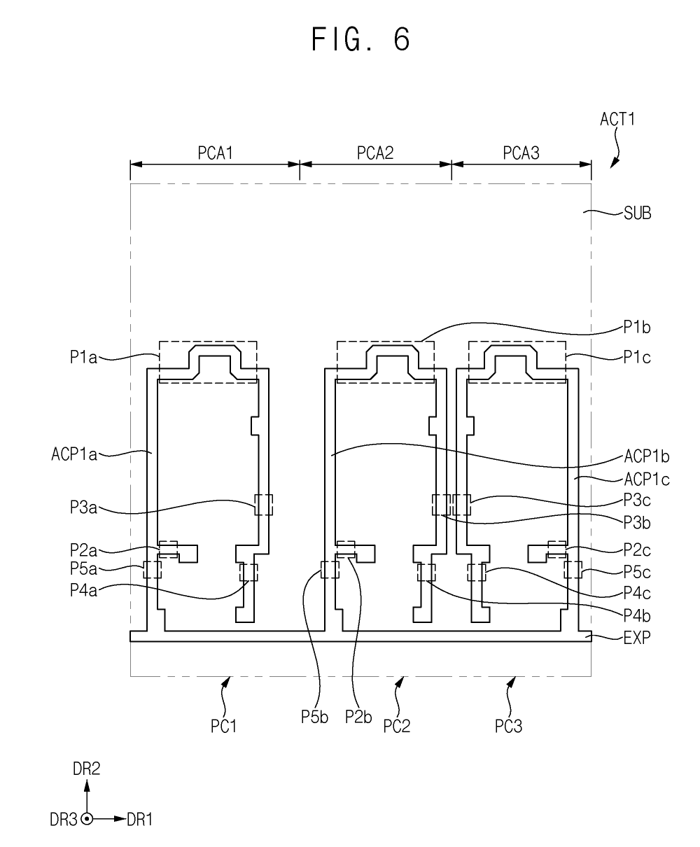

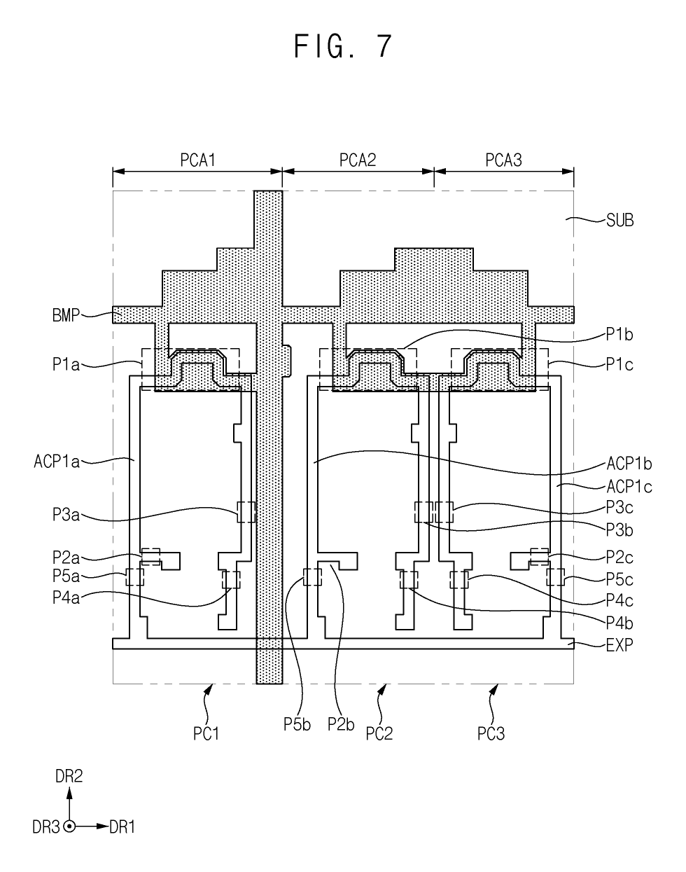

Referring further to FIGS. 6 and 7, the circuit layer CL may further include a first active layer ACT1 disposed on the lower metal layer BML. For example, the first active layer ACT1 may be disposed on a buffer layer BUF covering the lower metal layer BML. For example, the buffer layer BUF may include a silicon-based compound such as silicon oxide (SiOₓ), silicon nitride (SiNₓ), and silicon oxynitride (SiOₓN_{y}). These materials may be used alone or in combination with each other (see FIG. 20).

The first active layer ACT1 may include lower active patterns ACP1a, ACP1b, and ACP1c, and an extension pattern EXP. The lower active patterns ACP1a, ACP1b, and ACP1c may be disposed in the first, second, and third pixel circuit areas PCA1, PCA2, and PCA3, respectively. The extension pattern EXP may be connected to the lower active patterns ACP1a, ACP1b, and ACP1c and may extend in the first direction DR1. In addition, the lower active patterns ACP1a, ACP1b, and ACP1c and the extension pattern EXP may be integrally formed.

In the first pixel circuit area PCA1, the lower active pattern ACP1a may include first, second, third, fourth, and fifth portions P1a, P2a, P3a, P4a, and P5a spaced apart from each other. In the second pixel circuit area PCA2, the lower active pattern ACP1b may include first, second, third, fourth, and fifth portions P1b, P2b, P3b, P4b, and P5b spaced apart from each other. In addition, in the third pixel circuit area PCA3, the lower active pattern ACP1c may include first, second, third, fourth, and fifth portions P1c, P2c, P3c, P4c, and P5c spaced apart from each other.

Each of the first, second, third, fourth, and fifth portions P1a, P1b, P1c, P2a, P2b, P2c, P3a, P3b, P3c, P4a, P4b, P4c, P5a, P5b, and P5c may include a source region, a drain region, and a channel region between the source region and the drain region. The source region and the drain region may be regions doped with impurities. In some cases, the channel region might not be doped with impurities or may remain undoped.

In an embodiment, the first active layer ACT1 may include a silicon semiconductor such as amorphous silicon or polycrystalline silicon. However, the embodiments of the present disclosure are not necessarily limited thereto, and the first active layer ACT1 may include a metal oxide semiconductor.

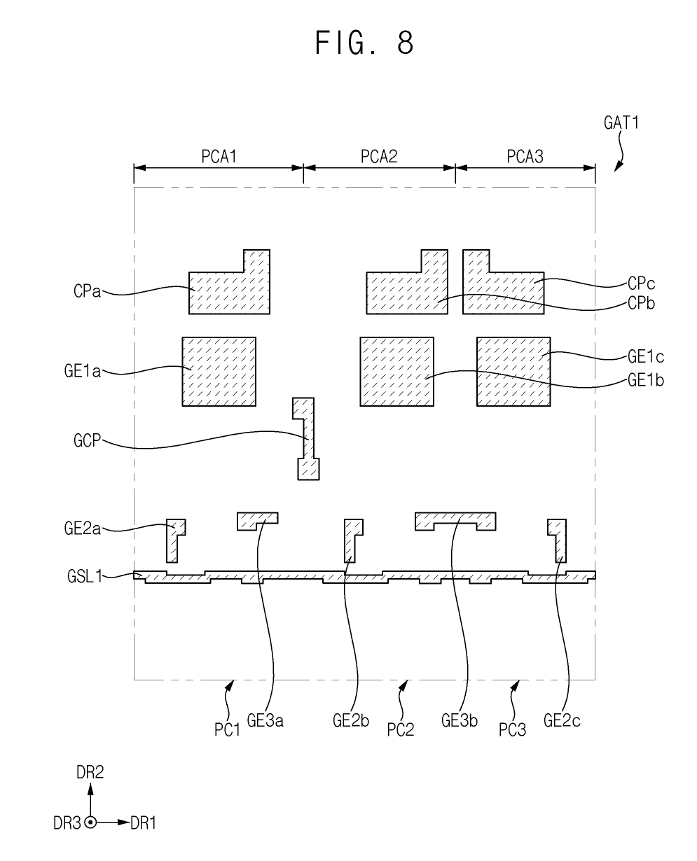

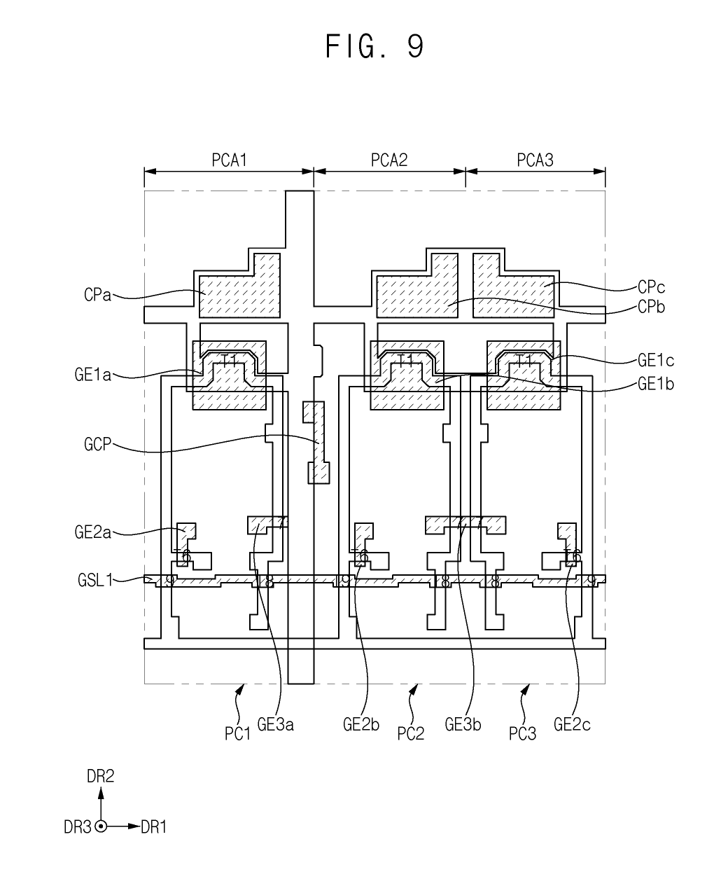

Referring further to FIGS. 8 and 9, the circuit layer CL may further include a first gate conductive layer GAT1 disposed on the first active layer ACT1. For example, a first insulating layer IL1 may be disposed on the first active layer ACT1, and the first gate conductive layer GAT1 may be disposed on the first insulating layer IL1. For example, the first insulating layer IL1 may include a silicon compound such as silicon oxide, silicon nitride, and silicon oxynitride. These materials may be used alone or in combination with each other (see FIG. 20). The first insulating layer IL1 may serve as a gate insulating layer electrically isolating the gate electrodes from the first active layer ACT1.

The first gate conductive layer GAT1 may include first gate electrodes GE1a, GE1b, and GE1c, second gate electrodes GE2a, GE2b, and GE2c, third gate electrodes GE3a and GE3b, a first gate signal line GSL1, a gate connection pattern GCP, and conductive patterns CPa, CPb, and CPc. The first gate electrodes GE1a, GE1b, and GE1c, the second gate electrodes GE2a, GE2b, and GE2c, the third gate electrodes GE3a and GE3b, the first gate signal line GSL1, the gate connection pattern GCP, and the conductive patterns CPa, CPb, and CPc may be disposed to be spaced apart from each other.

The first gate electrodes GE1a, GE1b, and GE1c, the second gate electrodes GE2a, GE2b, and GE2c, the third gate electrodes GE3a and GE3b, the first gate signal line GSL1, the gate connection pattern GCP, and the conductive patterns CPa, CPb, and CPc may be disposed in the same layer. For example, the first gate electrodes GE1a, GE1b, and GE1c, the second gate electrodes GE2a, GE2b, and GE2c, the third gate electrodes GE3a and GE3b, the first gate signal line GSL1, the gate connection pattern GCP, and the conductive patterns CPa, CPb, and CPc may include the same material and be formed through the same process.

The first gate electrodes GE1a, GE1b, and GE1c may be disposed in the first, second, and third pixel circuit areas PCA1, PCA2, and PCA3, respectively. Each of the first gate electrodes GE1a, GE1b, and GE1c may at least partially overlap the lower metal pattern BMP and the lower active pattern ACP1 in the plan view.

Accordingly, in the first pixel circuit area PCA1, the first transistor T1 may include the first gate electrode GE1a together with the first portion P1a of the lower active pattern ACP1a overlapping the first gate electrode GE1a. In the second pixel circuit area PCA2, first transistor T1 may include the first gate electrode GE1b together with the first portion P1b of the lower active pattern ACP1b overlapping the first gate electrode GE1b. In addition, in the third pixel circuit area PCA3, the first transistor T1 may include the first gate electrode GE1c together with the first portion P1c of the lower active pattern ACP1c overlapping the first gate electrode GE1c.

In each of the first, second, and third pixel circuit areas PCA1, PCA2, and PCA3, the first transistor T1 may further include a portion (e.g., a back gate electrode) of the lower metal pattern BMP overlapping the lower active patterns ACP1a, ACP1b, and ACP1c in the plan view. Here, the first transistor T1 may correspond to the first transistor T1 in FIG. 3.

The second gate electrodes GE2a, GE2b, and GE2c may be disposed in the first to third pixel circuit areas PCA1, PCA2, and PCA3, respectively. Each of the second gate electrodes GE2a, GE2b, and GE2c may at least partially overlap the lower active patterns ACP1a, ACP1b, and ACP1c, respectively.

Accordingly, in the first pixel circuit area PCA1, the sixth transistor T6 may include the second gate electrode GE2a together with the second portion P2a of the lower active pattern ACP1a overlapping the second gate electrode GE2a. In the second pixel circuit area PCA2, the sixth transistor T6 may include the second gate electrode GE2b together with the second portion P2b of the lower active pattern ACP1b overlapping the second gate electrode GE2b. In addition, in the third pixel circuit area PCA3, the sixth transistor T6 may include the second gate electrode GE2c together with the second portion P2c of the lower active pattern ACP1c overlapping the second gate electrode GE2c. Here, the sixth transistor T6 may correspond to the sixth transistor T6 in FIG. 3.

The third gate electrode GE3a may be disposed in the first pixel circuit area PCA1, and the third gate electrode GE3b may be disposed across the second and third pixel circuit areas PCA2and PCA3. Each of the third gate electrodes GE3a and GE3b may at least partially overlap the lower active patterns ACP1a, ACP1b, and ACP1c.

Accordingly, in the first pixel circuit area PCA1, the seventh transistor T7 may include the third gate electrode GE3a together with the third portion P3a of the lower active pattern ACP1a overlapping with the third gate electrode GE3a. In the second pixel circuit area PCA2, the seventh transistor T7 may include a portion of the third gate electrode GE3b together with the third portion P3b of the lower active pattern ACP1b overlapping the portion of the third gate electrode GE3b. In addition, in the third pixel circuit area PCA3, the seventh transistor T7 may include another portion of the third gate electrode GE3b together with the third portion P3c of the lower active pattern ACP1c overlapping another portion of the third gate electrode GE3b. Here, the seventh transistor T7 may correspond to the seventh transistor T7 of FIG. 3.

The first gate signal line GSL1 may extend in the first direction DR1. The first gate signal line GSL1 may receive a fourth gate signal (e.g., GB in FIG. 3). The first gate signal line GSL1 may at least partially overlap the lower active patterns ACP1a, ACP1b, and ACP1c in the plan view.

Accordingly, in the first pixel circuit area PCA1, the eighth transistor T8 may include the fourth portion P4a of the lower active pattern ACP1a and the portion (e.g., a gate electrode) of the first gate signal line GSL1 overlapping the fourth portion P4a, and the ninth transistor T9 may include the fifth portion P5a of the lower active pattern ACP1a and a different portion (e.g., a gate electrode) of the first gate signal line GSL1 overlapping the fifth portion P5a.

In the second pixel circuit area PCA2, the eighth transistor T8 may include the fourth portion P4b of the lower active pattern ACP1b and the portion (e.g., a gate electrode) of the first gate signal line GSL1 overlapping the fourth portion P4b, and the ninth transistor T9 may include the fifth portion P5b of the lower active pattern ACP1b and the portion (e.g., a gate electrode) of the first gate signal line GSL1 overlapping with the fifth portion P5b.

In the third pixel circuit area PCA3, the eighth transistor T8 may include the fourth portion P4c of the lower active pattern ACP1c and the portion (e.g., a gate electrode) of the first gate signal line GSL1 overlapping the fourth portion P4c, and the ninth transistor T9 may include the fifth portion P5c of the lower active pattern ACP1c and the portion (e.g., a gate electrode) of the first gate signal line GSL1 overlapping the fifth portion P5c.

The gate connection pattern GCP may receive an initialization voltage (e.g., VINT in FIG. 3). Each of the conductive patterns CPa, CPb, and CPc may overlap the lower metal pattern BMP in the plan view. The conductive pattern CPa may be referred to as a first conductive pattern, the conductive pattern CPb may be referred to as a second conductive pattern, and the conductive pattern CPc may be referred to as a third conductive pattern. In some cases, each conductive pattern may serve as a routing or contact structure for supplying voltages (e.g., VINT) to corresponding pixel transistors.

For example, the first gate conductive layer GAT1 may include a metal, an alloy, a metal nitride, a conductive metal oxide, a transparent conductive material, and other materials. These materials may be used alone or in combination with each other.

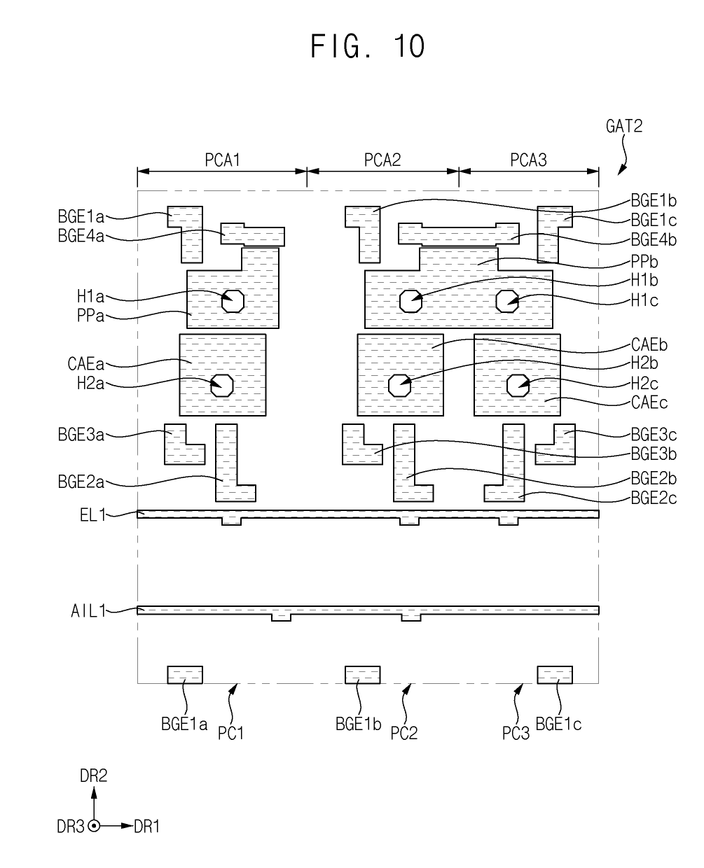

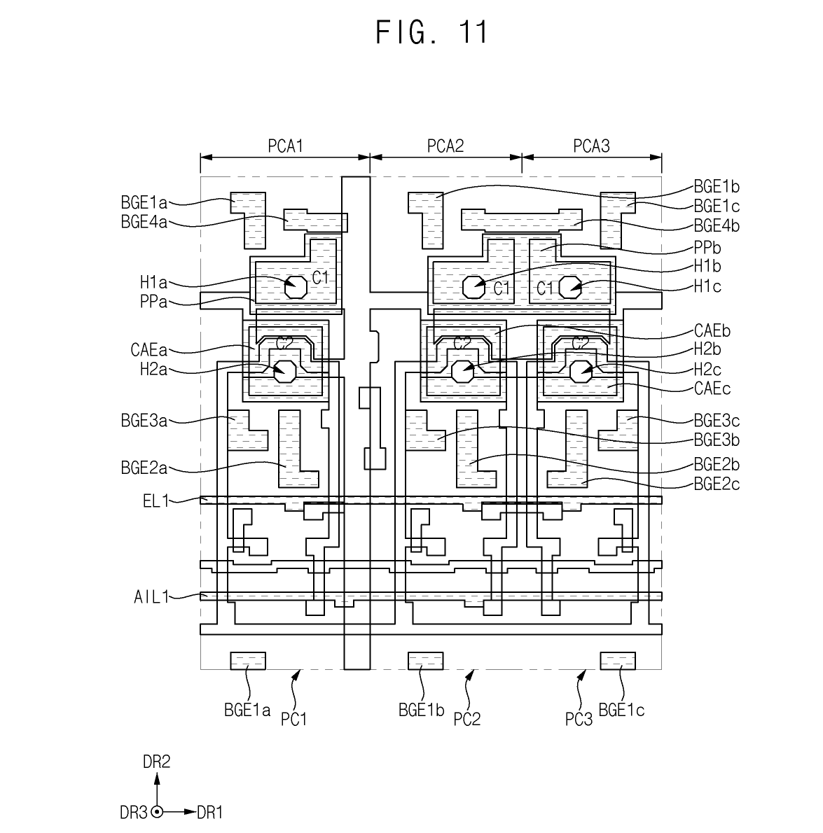

Referring further to FIGS. 10 and 11, the circuit layer CL may further include a second gate conductive layer GAT2 disposed on the first gate conductive layer GAT1. For example, a second insulating layer IL2 may be disposed on the first gate conductive layer GAT1, and the second gate conductive layer GAT2 may be disposed on the second insulating layer IL2. For example, the second insulating layer IL2 may include a silicon compound such as silicon oxide, silicon nitride, silicon oxynitride, and other insulating materials. These materials may be used alone or in combination with each other (see FIG. 20).

The second gate conductive layer GAT2 may include first back gate electrodes BGE1a, BGE1b, and BGE1c, second back gate electrodes BGE2a, BGE2b, and BGE2c, third back gate electrodes BGE3a, BGE3b, and BGE3c, fourth back gate electrodes BGE4a and BGE4b, capacitor electrodes CAEa, CAEb, and CAEc, power patterns PPa and PPb, a first emission control line EL1, and a first anode initialization voltage line AIL1 spaced apart from each other.

The first back gate electrodes BGE1a, BGE1b, and BGE1c, the second back gate electrodes BGE2a, BGE2b, and BGE2c, the third back gate electrodes BGE3a, BGE3b, and BGE3c, the fourth back gate electrodes BGE4a and BGE4b, the capacitor electrodes CAEa, CAEb, and CAEc, the power patterns PPa and PPb, the first emission control line EL1, and the first anode initialization voltage line AIL1 may be disposed in the same layer. For example, the first back gate electrodes BGE1a, BGE1b, and BGE1c, the second back gate electrodes BGE2a, BGE2b, and BGE2c, the third back gate electrodes BGE3a, BGE3b, and BGE3c, the fourth back gate electrodes BGE4a and BGE4b, the capacitor electrodes CAEa, CAEb, and CAEc, the power patterns PPa and PPb, the first emission control line EL1, and the first anode initialization voltage line AIL1 may include the same material and may be formed through the same process.

The first back gate electrodes BGE1a, BGE1b, and BGE1c may be disposed in the first, second, and third pixel circuit areas PCA1, PCA2, and PCA3, respectively. The second back gate electrodes BGE2a, BGE2b, and BGE2c may be disposed in the first, second, and third pixel circuit areas PCA1, PCA2, and PCA3, respectively. The third back gate electrodes BGE3a, BGE3b, and BGE3c may be disposed in the first, second, and third pixel circuit areas PCA1, PCA2, and PCA3, respectively. In addition, the fourth back gate electrode BGE4a may be disposed in the first pixel circuit area PCA1, and the fourth back gate electrode BGE4b may be disposed across the second and third pixel circuit areas PCA2 and PCA3.

The power pattern PPa may be disposed in the first pixel circuit area PCA1, and the power pattern PPb may be disposed across the second and third pixel circuit areas PCA2 and PCA3. The power patterns PPa and PPb may receive a driving voltage (e.g., ELVDD in FIG. 3). For example, the power pattern PPb may include a first portion and a second portion symmetrical with respect to a virtual symmetry line extending in the second direction DR2. The power pattern PPa may be referred to as a first power pattern, a portion of the power pattern PPb overlapping the second pixel circuit area PCA2 may be referred to as a second power pattern, and another portion of the power pattern PPb overlapping the third pixel circuit area PCA3 may be referred to as a third power pattern. For example, the second power pattern and the third power pattern may be integrally formed.

In the first pixel circuit area PCA1, the power pattern PPa may at least partially overlap the conductive pattern CPa in the plan view. Accordingly, the first capacitor C1 may include the power pattern PPa together with the conductive pattern CPa.

In the second and third pixel circuit areas PCA2 and PCA3, the power pattern PPb may at least partially overlap each of the conductive patterns CPb and CPc in the plan view. Accordingly, in the second pixel circuit area PCA2, the first capacitor C1 may include a portion of the power pattern PPb overlapping the conductive pattern CPb together with the conductive pattern CPb, and in the third pixel circuit area PCA3, the first capacitor C1 may include another portion of the power pattern PPb overlapping the conductive pattern CPc together with the conductive pattern CPc.

Here, the first capacitor C1 may correspond to the first capacitor C1 in FIG. 3. The first capacitor C1 disposed in the first pixel circuit area PCA1 may be referred to as a first storage capacitor, the first capacitor C1 disposed in the second pixel circuit area PCA2 may be referred to as a second storage capacitor, and the first capacitor C1 disposed in the third pixel circuit area PCA3 may be referred to as a third storage capacitor.

A first hole H1a may be defined in the power pattern PPa, and first holes H1b and H1c may be defined in the power pattern PPb. In the first pixel circuit area PCA1, the first hole H1a may expose at least a portion of the conductive pattern CPa, and in the second and third pixel circuit areas PCA2 and PCA3, the first hole H1b may expose at least a portion of the conductive pattern CPb and the first hole H1c may expose at least a portion of the conductive pattern CPc.

The capacitor electrodes CAEa, CAEb, and CAEc may be disposed in the first, second, and third pixel circuit areas PCA1, PCA2, and PCA3, respectively. The capacitor electrodes CAEa, CAEb, and CAEc may at least partially overlap the first gate electrodes GE1a, GE1b, and GE1c in the plan view, respectively. Accordingly, in the first pixel circuit area PCA1, the second capacitor C2 may include the capacitor electrode CAEa together with the first gate electrode GE1a, in the second pixel circuit area PCA2, the second capacitor C2 may include the capacitor electrode CAEb together with the first gate electrode GE1b, and in the third pixel circuit area PCA3, the second capacitor C2 may include the capacitor electrode CAEc together with the first gate electrode GE1c.

Second holes H2a, H2b, and H2c may be defined in the capacitor electrodes CAEa, CAEb, and CAEc, respectively. In the first pixel circuit area PCA1, the second hole H2a may expose at least a portion of the first gate electrode GE1a, in the second pixel circuit area PCA2, the second hole H2b may expose at least a portion of the first gate electrode GE1b, and in the third pixel circuit area PCA3, the second hole H2c exposes at least a portion of the first gate electrode GE1c.

The first emission control line EL1 may extend in the first direction DR1. The first emission control line EL1 may at least partially overlap each of the lower active patterns ACP1a, ACP1b, and ACP1c in the plan view. The first emission control line EL1 may receive a second emission control signal (e.g., EM2 in FIG. 3). In addition, the first emission control line EL1 may be adjacent to the third gate electrodes GE3a and GE3b. The emission control signal EM2 supplied through the first emission control line EL1 may control switching of the seventh transistor T7 in each pixel circuit area.

The first anode initialization voltage line AIL1 may extend in the first direction DR1. The first anode initialization voltage line AIL1 may at least partially overlap each of the lower active patterns ACP1a, ACP1b, and ACP1c in the plan view. The first anode initialization voltage line AIL1 may receive an anode initialization voltage (e.g., VAINT in FIG. 3). The first anode initialization voltage line AIL1 may be adjacent to the extension pattern EXP. For example, the first anode initialization voltage line AIL1 may transmit the anode initialization voltage to the second pixel driving circuit part PC2.

For example, the second gate conductive layer GAT2 may include a metal, an alloy, a metal nitride, a conductive metal oxide, a transparent conductive material, and other conductive materials. These materials may be used alone or in combination with each other. The second gate conductive layer GAT2 may serve as a signal routing layer and a control electrode layer for back gates and capacitors formed over the layers. Accordingly, the second gate conductive layer GAT2 may be disposed above the first gate conductive layer GAT1, and may form part of a multi-layer stack configured to vertically align power and control signals with corresponding transistor elements in the pixel circuit areas.

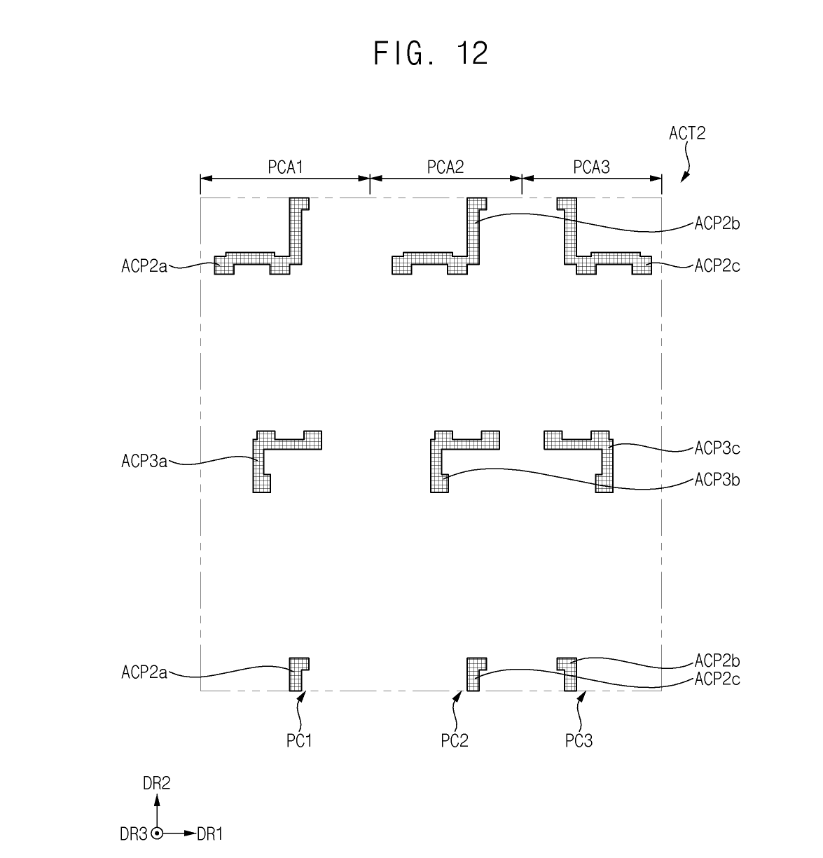

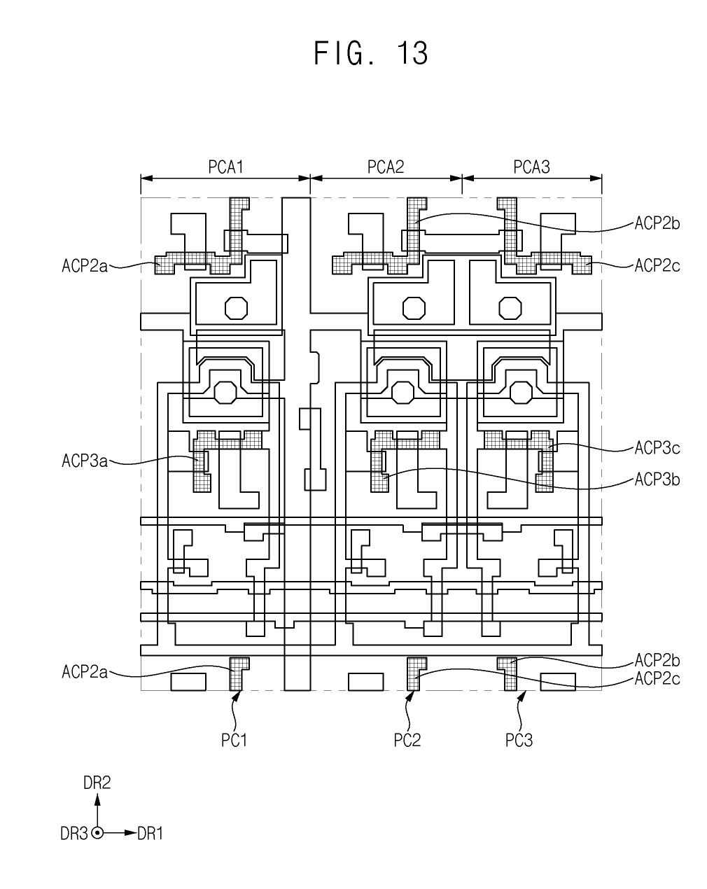

Referring further to FIGS. 12 and 13, the circuit layer CL may further include a second active layer ACT2 disposed on the second gate conductive layer GAT2. For example, a third insulating layer IL3 may be disposed on the second gate conductive layer GAT2, and the second active layer ACT2 may be disposed on the third insulating layer IL3. For example, the third insulating layer IL3 may include a silicon compound such as silicon oxide, silicon nitride, silicon oxynitride, and the like. These materials may be used alone or in combination with each other (see FIG. 20). In some cases, the third insulating layer IL3 may electrically insulate the second active layer ACT2 from the gate electrodes and conductive structures, and may function as a gate insulating layer for transistors formed in the upper layers.

The second active layer ACT2 may include first upper active patterns ACP2a, ACP2b, and ACP2c, and second upper active patterns ACP3a, ACP3b, and ACP3c spaced apart from each other. The first upper active patterns ACP2a, ACP2b, and ACP2c and the second upper active patterns ACP3a, ACP3b, and ACP3c may be disposed in the same layer. For example, the first upper active patterns ACP2a, ACP2b, and ACP2c and the second upper active patterns ACP3a, ACP3b, and ACP3c may include the same material and may be formed through the same process. These upper active patterns may serve as source, drain, or channel regions of transistors formed in upper layers of the pixel driving circuit.

The first upper active patterns ACP2a, ACP2b, and ACP2c may be disposed in the first, second, and third pixel circuit areas PCA1, PCA2, and PCA3, respectively. In the first pixel circuit area PCA1, the first upper active pattern ACP2a may at least partially overlap each of the first back gate electrode BGE1a and the fourth back gate electrode BGE4a in the plan view. In the second pixel circuit area PCA2, the first upper active pattern ACP2b may at least partially overlap the first back gate electrode BGE1b and a portion of the fourth back gate electrode BGE4b in the plan view. In the third pixel circuit region PCA3, the first upper active pattern ACP2c may at least partially overlap the first back gate electrode BGE1c and another portion of the fourth back gate electrode BGE4b in the plan view.

The second upper active patterns ACP3a, ACP3b, and ACP3c may be disposed in the first, second, and third pixel circuit areas PCA1, PCA2, and PCA3, respectively. In the first pixel circuit area PCA1, the second upper active pattern ACP3a may at least partially overlap each of the second back gate electrode BGE2a and the third back gate electrode BGE3a in the plan view. In the second pixel circuit area PCA2, the second upper active pattern ACP3b may at least partially overlap each of the second back gate electrode BGE2b and the third back gate electrode BGE3b in the plan view. In the third pixel circuit area PCA3, the second upper active pattern ACP3c may at least partially overlap each of the second back gate electrode BGE2c and the third back gate electrode BGE3c in the plan view. The overlap between the upper active patterns ACP2a, ACP2b, and ACP2c and back gate electrodes BGE1, BGE2, BGE3, and BGE4 enables the formation of transistors with back gate bias control, which may enahnce threshold voltage stability or reduce leakage current.

In an embodiment, the second active layer ACT2 may include a metal oxide semiconductor. Examples of the metal oxide semiconductor may include zinc oxide (e.g., ZnO or ZnO₂), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and/or other semiconductor materials. These materials may be used alone or in combination with each other. However, embodiments of the present disclosure are not necessarily limited thereto.

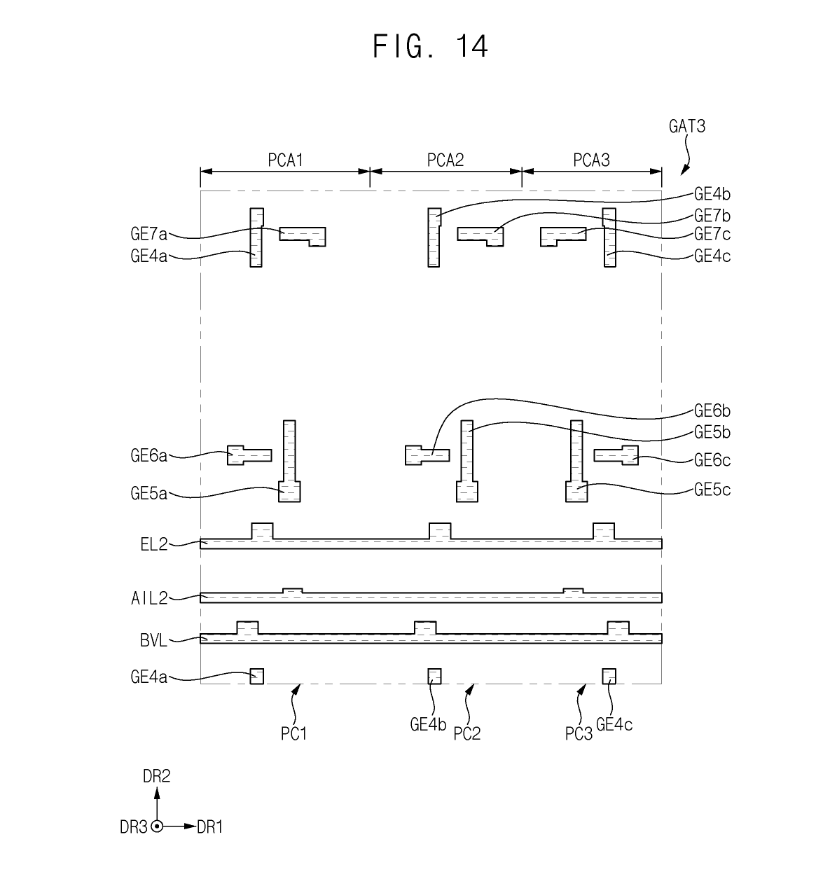

Referring further to FIGS. 14 and 15, the circuit layer CL may further include a third gate conductive layer GAT3 disposed on the second active layer ACT2. For example, a fourth insulating layer IL4 may be disposed on the second active layer ACT2, and the third gate conductive layer GAT3 may be disposed on the fourth insulating layer IL4. For example, the fourth insulating layer IL4 may include a silicon compound such as silicon oxide, silicon nitride, silicon oxynitride, and other insulating materials. These materials may be used alone or in combination with each other (see FIG. 20).

The third gate conductive layer GAT3 may include fourth gate electrodes GE4a, GE4b, and GE4c, fifth gate electrodes GE5a, GE5b, and GE5c, sixth gate electrodes GE6a, GE6b, and GE6c, seventh gate electrodes GE7a, GE7b, and GE7c, a second emission control line EL2, a second anode initialization voltage line AIL2, and a bias voltage line BVL spaced apart from each other.

The fourth gate electrodes GE4a, GE4b, and GE4c, the fifth gate electrodes GE5a, GE5b, and GE5c, the sixth gate electrodes GE6a, GE6b, and GE6c, the seventh gate electrodes GE7a, GE7b, and GE7c, the second emission control line EL2, the second anode initialization voltage line AIL2, and the bias voltage line BVL may be disposed in the same layer. In addition, the fourth gate electrodes GE4a, GE4b, and GE4c, the fifth gate electrodes GE5a, GE5b, and GE5c, the sixth gate electrodes GE6a, GE6b, and GE6c, the seventh gate electrodes GE7a, GE7b, and GE7c, the second emission control line EL2, the second anode initialization voltage line AIL2, and the bias voltage line BVL may include the same material and be formed through the same process.

The fourth gate electrodes GE4a, GE4b, and GE4c may be disposed in the first, second, and third pixel circuit areas PCA1, PCA2, and PCA3, respectively. The fourth gate electrodes GE4a, GE4b, and GE4c may at least partially overlap the first upper active patterns ACP2a, ACP2b, and ACP2c and the first back gate electrodes BGE1a, BGE1b, and BGE1c in the plan view, respectively.

Accordingly, in the first pixel circuit area PCA1, the second transistor T2 may include the fourth gate electrode GE4a together with the first back gate electrode BGE1a and a portion of the first upper active pattern ACP2a overlapping the fourth gate electrode GE4a. In the second pixel circuit area PCA2, the second transistor T2 may include the fourth gate electrode GE4b together with the first back gate electrode BGE1b and a portion of the first upper active pattern ACP2b overlapping the fourth gate electrode GE4b. In the third pixel circuit area PCA3, the second transistor T2 may include the fourth gate electrode together with the first back gate electrode BGE1c and a portion of the first upper active pattern ACP2c overlapping the fourth gate electrode GE4c. Here, the second transistor T2 may correspond to the second transistor T2 in FIG. 3.

The fifth gate electrodes GE5a, GE5b, and GE5c may be disposed in the first, second, and third pixel circuit areas PCA1, PCA2, and PCA3, respectively. The fifth gate electrodes GE5a, GE5b, and GE5c may at least partially overlap the second upper active patterns ACP3a, ACP3b, and ACP3c and the second back gate electrodes BGE2a, BGE2b, and BGE2c in the plan view, respectively.

Accordingly, in the first pixel circuit area PCA1, the third transistor T3 may include the fifth gate electrode GE5a together with the second back gate electrode BGE2a and a portion of the second upper active pattern ACP3a overlapping the fifth gate electrode GE5a. In the second pixel circuit area PCA2, the third transistor T3 may include the fifth gate electrode GE5b together with the second back gate electrode BGE2b and a portion of the second upper active pattern ACP3b overlapping the fifth gate electrode GE5b. In the third pixel circuit area PCA3, the third transistor T3 may include the fifth gate electrode GE5c together with the second back gate electrode BGE2b and a portion of the second upper active pattern ACP3c overlapping the fifth gate electrode GE5c. Here, the third transistor T3 may correspond to the third transistor T3 in FIG. 3.

The sixth gate electrodes GE6a, GE6b, and GE6c may be disposed in the first, second, and third pixel circuit areas PCA1, PCA2, and PCA3, respectively. The sixth gate electrodes GE6a, GE6b, and GE6c may at least partially overlap the second upper active patterns ACP3a, ACP3b, and ACP3c and the third back gate electrodes BGE3a, BGE3b, and BGE3c in the plan view, respectively.

Accordingly, in the first pixel circuit area PCA1, the fourth transistor T4 may include the sixth gate electrode GE6a together with the third back gate electrode BGE3a and a portion of the second upper active pattern ACP3a overlapping the sixth gate electrode GE6a. In the second pixel circuit area PCA2, the fourth transistor T4 may include the sixth gate electrode GE6b together with the third back gate electrode BGE3b and a portion of the second upper active pattern ACP3b overlapping the sixth gate electrode GE6b. In the third pixel circuit area PCA3, the fourth transistor T4 may include the sixth gate electrode GE6c together with the third back gate electrode BGE3c and a portion of the second upper active pattern ACP3c overlapping the sixth gate electrode GE6c. Here, the fourth transistor T4 may correspond to the fourth transistor T4 in FIG. 3.

The seventh gate electrodes GE7a, GE7b, and GE7c may be disposed in the first, second, and third pixel circuit areas PCA1, PCA2, and PCA3, respectively. The seventh gate electrodes GE7a, GE7b, and GE7c may at least partially overlap the first upper active patterns ACP2a, ACP2b, and ACP2c and the fourth back gate electrodes BGE4a, BGE4b, and BGE4c in the plan view, respectively.

Accordingly, in the first pixel circuit area PCA1, the fifth transistor T5 may include the seventh gate electrode GE7a together with the fourth back gate electrode BGE4a and another portion of the first upper active pattern ACP2a overlapping the seventh gate electrode GE7a. In the second pixel circuit area PCA2, the fifth transistor T5 may include the seventh gate electrode GE7b together with the fourth back gate electrode BGE4b and another portion of the first upper active pattern ACP2b overlapping the seventh gate electrode GE7b. In the third pixel circuit area PCA3, the fifth transistor T5 may include the seventh gate electrode GE7c together with the fourth back gate electrode BGE4c and a different portion of the first upper active pattern ACP2c overlapping the seventh gate electrode GE7c. Here, the fifth transistor T5 may correspond to the fifth transistor T5 in FIG. 3.

Accordingly, the first, second, and third pixel driving circuit parts PC1, PC2, and PC3, each including the first, second, third, fourth, fifth, sixth, seventh, eighth, and ninth transistors T1, T2, T3, T4, T5, T6, T7, T8, and T9, the first capacitor C1, and the second capacitor C2, may be formed the first, second, and third pixel circuit areas PCA1, PCA2, and PCA3, respectively. In this configuration, the first transistor T1 may be referred to as a driving transistor, and each of the second, third, fourth, fifth, sixth, seventh, eighth, ninth transistors T2, T3, T4, T5, T6, T7, T8, and T9 may be referred to as a switching transistor.

The second emission control line EL2 may extend in the first direction DR1. The second emission control line EL2 may at least partially overlap the second gate electrodes GE2a, GE2b, and GE2c in the plan view. The second emission control line EL2 may receive a first emission control signal (e.g., EM1 in FIG. 3).

The second anode initialization voltage line AIL2 may extend in the first direction DR1. The second anode initialization voltage line AIL2 may be disposed between the first gate signal line GSL1 and the first anode initialization voltage line AIL1 in the plan view. The second initialization voltage line AIL2 may receive an anode initialization voltage (e.g., VAINT in FIG. 3). For example, the second initialization voltage line AIL2 may transmit the anode initialization voltage to the first and third pixel driving circuit parts PC1 and PC3. In some cases, the anode initialization voltage applied through the second initialization voltage line AIL2 may reset the potential of the anode of the light-emitting element LED to a predetermined state before emission begins.

The bias voltage line BVL may extend in the first direction DR1. The bias voltage line BVL may at least partially overlap the extension pattern EXP in the plan view. The bias voltage line BVL may receive a bias voltage (e.g., VOBS in FIG. 3).

For example, the third gate conductive layer GAT3 may include a metal, an alloy, a metal nitride, a conductive metal oxide, a transparent conductive material, and other conductive materials. These materials may be used alone or in combination with each other.

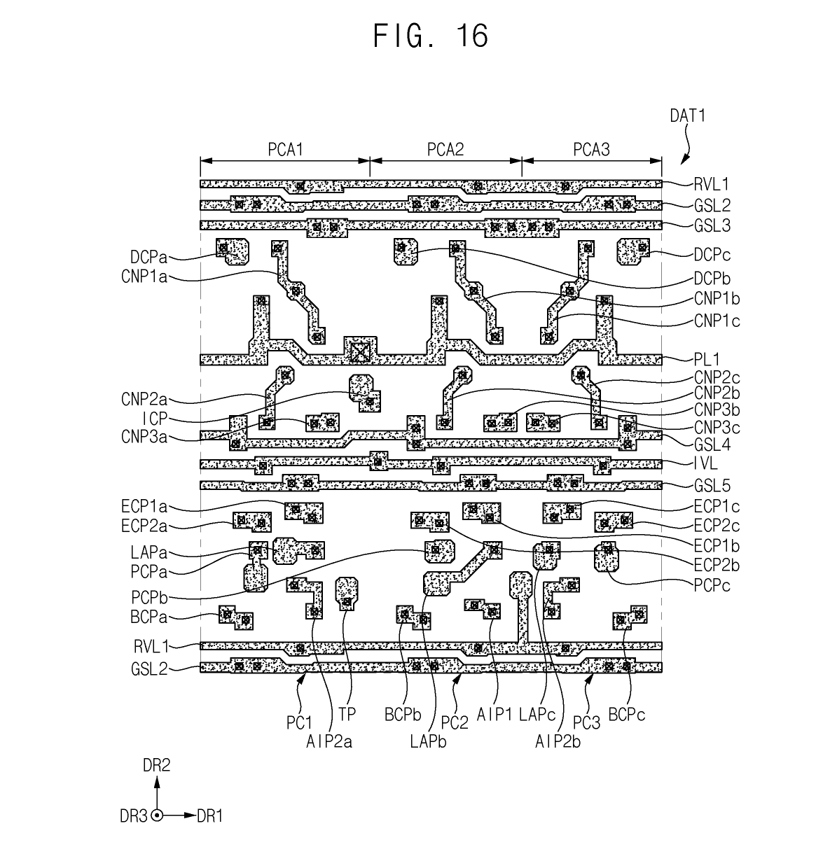

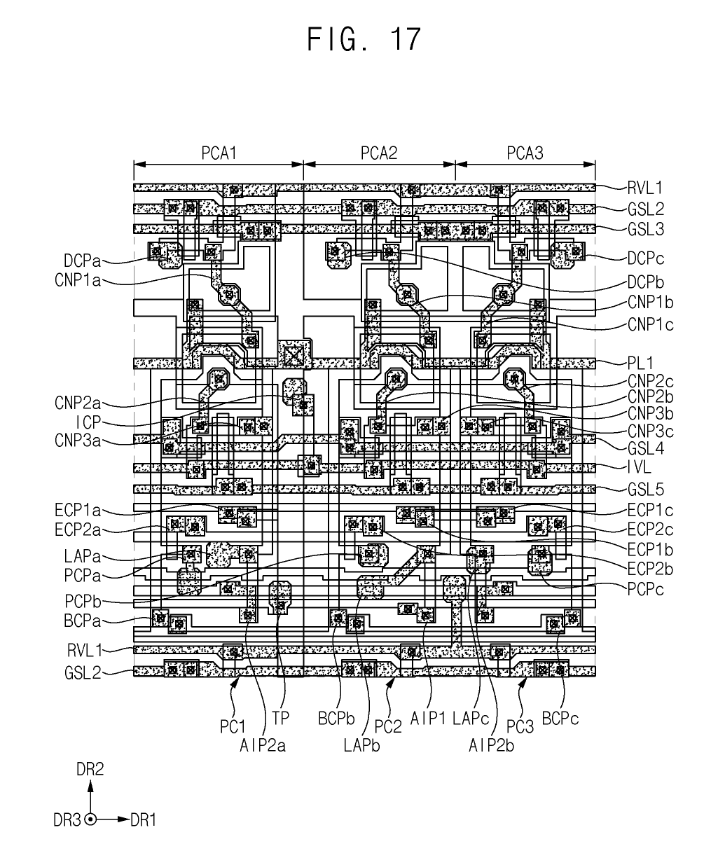

Referring to FIGS. 16 and 17, the circuit layer CL may further include a first data conductive layer DAT1 disposed on the third gate conductive layer GAT3. For example, a fifth insulating layer IL5 may be disposed on the third gate conductive layer GAT3, and the first data conductive layer DAT1 may be disposed on the fifth insulating layer IL5. For example, the fifth insulating layer IL5 may include silicon compounds such as silicon oxide, silicon nitride, silicon oxynitride, and the like. These materials may be used alone or in combination with each other (see FIG. 20). The fifth insulating layer IL5 may electrically insulate the gate structures of the third gate conductive layer GAT3 from the overlying signal and routing lines in the first data conductive layer DAT1.

The first data conductive layer DAT1 may include first connection patterns CNP1a, CNP1b, and CNP1c, second connection patterns CNP2a, CNP2b, and CNP2c, third connection patterns CNP3a, CNP3b, and CNP3c, data connection patterns DCPa, DCPb, and DCPc, an initialization connection pattern ICP, first emission control connection patterns ECP1a, ECP1b, and ECP1c, second emission control connection patterns ECP2a, ECP2b, and ECP2c, power connection patterns PCPa, PCPb, and PCPc, bias connection patterns BCPa, BCPb, and BCPc, a transmission pattern TP, a first anode initialization connection pattern AIP1, second anode initialization connection patterns AIP2a and AIP2b, lower anode connection patterns LAPa, LAPb, and LAPc, a first power line PL1, an initialization voltage line IVL, a first reference voltage line RVL1, a second gate signal line GSL2, a third gate signal line GSL3, a fourth gate signal line GSL4, and a fifth gate signal line GSL5 spaced apart from each other.

The first connection patterns CNP1a, CNP1b, and CNP1c, the second connection patterns CNP2a, CNP2b, and CNP2c, the third connection patterns CNP3a, CNP3b, and CNP3c, the data connection patterns DCPa, DCPb, and DCPc, the initialization connection pattern ICP, the first emission control connection patterns ECP1a, ECP1b, and ECP1c, the second emission control connection patterns ECP2a, ECP2b, and ECP2c, the power connection patterns PCPa, PCPb, and PCPc, the bias connection patterns BCPa, BCPb, and BCPc, the transmission pattern TP, the first anode initialization connection pattern AIP1, the second anode initialization connection patterns AIP2a and AIP2b, the lower anode connection patterns LAPa, LAPb, and LAPc, the first power line PL1, the initialization voltage line IVL, the first reference voltage line RVL1, the second gate signal line GSL2, the third gate signal line GSL3, the fourth gate signal line GSL4, and the fifth gate signal line GSL5 may be disposed in the same layer, may include the same material, and may be formed through the same process.

The first connection patterns CNP1a, CNP1b, and CNP1c may be disposed in the first, second, and third pixel circuit areas PCA1, PCA2, and PCA3, respectively. In each of the first, second, and third pixel circuit areas PCA1, PCA2, and PCA3, the first connection patterns CNP1a, CNP1b, and CNP1c may connect the corresponding first upper active patterns ACP2a, ACP2b, and ACP2c and the corresponding capacitor electrodes CAE1a, CAE1b, and CAE1c through contact holes, respectively. In addition, the first connection patterns CNP1a, CNP1b, and CNP1c may connect the corresponding conductive patterns CPa, CPb, and CPc exposed by the first holes H1a, H1b, and H1c through contact holes, respectively. Accordingly, each of the first connection patterns CNP1a, CNP1b, and CNP1c may electrically connect the first capacitor C1, the second capacitor C2, the second transistor T2, and the fifth transistor T5.

The second connection patterns CNP2a, CNP2b, and CNP2c may be disposed in the first, second, and third pixel circuit areas PCA1, PCA2, and PCA3, respectively. In each of the first, second, and third pixel circuit areas PCA1, PCA2, and PCA3, the second connection patterns CNP2a, CNP2b, and CNP2c may connect the corresponding second upper active patterns ACP3a, ACP3b, and ACP3c and the corresponding first gate electrodes GE1a, GE1b, and GE1c exposed by the second holes H2a, H2b, and H2c through contact holes, respectively. Accordingly, each of the second connection patterns CNP2a, CNP2b, and CNP2c may electrically connect the second capacitor C2, the third transistor T3, and the fourth transistor T4.

The third connection patterns CNP3a, CNP3b, and CNP3c may be disposed in the first, second, and third pixel circuit areas PCA1, PCA2, and PCA3. In each of the first, second, and third pixel circuit areas PCA1, PCA2, and PCA3, the third connection patterns CNP3a, CNP3b, and CNP3c may connect the corresponding lower active patterns ACP1a, ACP1b, and ACP1c and the corresponding second upper active patterns ACP3a, ACP3b, and ACP3c through contact holes, respectively. Accordingly, each of the third connection patterns CNP3a, CNP3b, and CNP3c may electrically connect the third transistor T3, the first transistor T1, and the seventh transistor T7.

The data connection patterns DCPa, DCPb, and DCPc may be disposed in the first, second, and third pixel circuit areas PCA1, PCA2, and PCA3, respectively. In each of the first, second, and third pixel circuit areas PCA1, PCA2, and PCA3, the data connection patterns DCPa, DCPb, and DCPc may be connected to the corresponding first upper active patterns ACP2a, ACP2b, and ACP2c. Accordingly, the data connection patterns DCPa, DCPb, and DCPc may transmit data voltages (e.g., VDATA in FIG. 3) to the corresponding first upper active patterns ACP2a, ACP2b, and ACP2c.

The initialization connection pattern ICP may be connected to the gate connection pattern GCP through a contact hole. Accordingly, the initialization connection pattern ICP may transmit an initialization voltage (e.g., VINT in FIG. 3) to the gate connection pattern GCP. In some cases, the gate connection pattern GCP may then distribute the initialization voltage VINT to gate electrodes associated with initialization transistors in the pixel circuit.

The first emission control connection patterns ECP1a, ECP1b, and ECP1c may be disposed in the first, second, and third pixel circuit areas PCA1, PCA2, and PCA3, respectively. In each of the first, second, and third pixel circuit areas PCA1, PCA2, and PCA3, the first emission control connection patterns ECP1a, ECP1b, and ECP1c may connect the corresponding third gate electrodes GE3a, GE3b, and GE3c and the first emission control line EL1 through contact holes, respectively. Accordingly, the second emission control signal (e.g., EM2 in FIG. 3) applied to the first emission control line EL1 may be transmitted to the third gate electrodes GE3a, GE3b, and GE3c through the first emission control connection patterns ECP1a, ECP1b, and ECP1c.

The second emission control connection patterns ECP2a, ECP2b, and ECP2c may be disposed in the first, second, and third pixel circuit areas PCA1, PCA2, and PCA3, respectively. In each of the first, second, and third pixel circuit areas PCA1, PCA2, and PCA3, the second emission control connection patterns ECP2a, ECP2b, and ECP2c may connect the corresponding second gate electrodes GE2a, GE2b, and GE2c and the second emission control line EL2 through contact holes, respectively. Accordingly, the first emission control signal (e.g., EM1 in FIG. 3) applied to the second emission control line EL2 may be transmitted to the second gate electrodes GE2a, GE2b, and GE2c through the second emission control connection patterns ECP2a, ECP2b, and ECP2c.

The power connection patterns PCPa, PCPb, and PCPc may be disposed in the first, second, and third pixel circuit areas PCA1, PCA2, and PCA3, respectively. In each of the first, second, and third pixel circuit areas PCA1, PCA2, and PCA3, the power connection patterns PCPa, PCPb, and PCPc may be connected to the corresponding lower active patterns ACP1a, ACP1b, and ACP1c through contact holes, respectively. Accordingly, the power connection patterns PCPa, PCPb, and PCPc may transmit a driving voltage (e.g., ELVDD in FIG. 3) to the second portions P2a, P2b, and P2c of the corresponding lower active patterns ACP1a, ACP1b, and ACP1c, respectively.

The bias connection patterns BCPa, BCPb, and BCPc may be disposed in the first, second, and third pixel circuit areas PCA1, PCA2, and PCA3, respectively. In each of the first, second, and third pixel circuit areas PCA1, PCA2, and PCA3, the bias connection patterns BCPa, BCPb, and BCPc may be connected to the bias voltage line BVL and the corresponding lower active patterns ACP1a, ACP1b, and ACP1c through contact holes, respectively. Accordingly, the bias connection patterns BCPa, BCPb, and BCPc may transmit a bias voltage (e.g., VOBS in FIG. 3) to the fifth portions P5a, P5b, and P5c of the corresponding lower active patterns ACP1a, ACP1b, and ACP1c, respectively.

The transmission pattern TP may be connected to the first anode initialization voltage line AIL1 through a contact hole. The transmission pattern TP may transmit an anode initialization voltage (e.g., VAINT in FIG. 3) to the first anode initialization voltage line AIL1.

The first anode initialization connection pattern AIP1 may connect the first anode initialization voltage line AIL1 and the lower anode pattern ACP1b through contact holes. Accordingly, the anode initialization voltage applied to the first anode initialization voltage line AIL1 may be transmitted to the fourth portion P4b of the lower anode pattern ACP1b through the first anode initialization connection pattern AIP1.

The second anode initialization connection patterns AIP2a and AIP2b may be disposed in the first and third pixel circuit areas PCA1 and PCA3, respectively. In each of the first and third pixel circuit areas PCA1 and PCA3, the second anode initialization connection patterns AIP2a and AIP2b may connect the second anode initialization voltage line AIL2 and the corresponding lower active patterns ACP1a and ACP1c, respectively. Accordingly, the anode initialization voltage applied to the second anode initialization voltage line AIL2 may be transmitted to the fourth portions P4a and P4c of the corresponding lower active patterns ACP1a and ACP1c through the second anode initialization connection patterns AIP2a and AIP2b.

The first power line PL1 may extend in the first direction DR1. The first power line PL1 may receive a driving voltage (e.g., ELVDD in FIG. 3). The first power line PL1 may at least partially overlap the second capacitors C2 in the plan view. In addition, the first power line PL1 may be connected to the lower metal pattern BMP, and the power patterns PPa and PPb through contact holes. Accordingly, the first power line PL1 may transmit the driving voltage to the lower metal pattern BMP and the power patterns PPa and PPb.

The initialization voltage line IVL may extend in the first direction DR1. The initialization voltage line IVL may receive an initialization voltage (e.g., VINT in FIG. 3). The initialization voltage line IVL may be located between the fourth gate signal line GSL4 and the fifth gate signal line GSL5 in the plan view. In addition, the initialization voltage line IVL may be connected to the gate connection pattern GCP and the second upper active patterns ACP3a, ACP3b, and ACP3c through contact holes. Accordingly, the initialization voltage line IVL may transmit the initialization voltage to the gate connection pattern GCP and the second upper active patterns ACP3a, ACP3b, and ACP3c.

The first reference voltage line RVL1 may extend in the first direction DR1. The first reference voltage line RVL1 may receive a reference voltage (e.g., VREF in FIG. 3). The first reference voltage line RVL1 may be connected to the first upper active patterns ACP2a, ACP2b, and ACP2c through contact holes. Accordingly, the first reference voltage line RVL1 may transmit the reference voltage to the first upper active patterns ACP2a, ACP2b, and ACP2c.

The second gate signal line GSL2 may extend in the first direction DR1. The second gate signal line GSL2 may receive a first gate signal (e.g., GW in FIG. 3). The second gate signal line GSL2 may be connected to the first back gate electrodes BGE1a, BGE1b, and BGE1c and the fourth gate electrodes GE4a, GE4b, and GE4c through contact holes. Accordingly, the second gate signal line GSL2 may transmit the first gate signal to the first back gate electrodes BGE1a, BGE1b, and BGE1c and the fourth gate electrodes GE4a, GE4b, and GE4c. In addition, the second gate signal line GSL2 may electrically connect the first back gate electrodes BGE1a, BGE1b, and BGE1c and the corresponding fourth gate electrodes GE4a, GE4b, and GE4c.

The third gate signal line GSL3 may extend in the first direction DR1. The third gate signal line GSL3 may receive a second gate signal (e.g., GC in FIG. 3). The third gate signal line GSL3 may be connected to the fourth back gate electrodes BGE4a and BGE4b and the seventh gate electrodes GE7a, GE7b, and GE7c through contact holes. Accordingly, the third gate signal line GSL3 may transmit the second gate signal to the fourth back gate electrodes BGE4a and BGE4b and the seventh gate electrodes GE7a, GE7b, and GE7c. In addition, the third gate signal line GSL3 may electrically connect the fourth back gate electrodes BGE4a and BGE4b and the corresponding seventh gate electrodes GE7a, GE7b, and GE7c.

The fourth gate signal line GSL4 may extend in the first direction DR1. The fourth gate signal line GSL4 may receive a third gate signal (e.g., GI in FIG. 3). The fourth gate signal line GSL4 may be connected to the third back gate electrodes BGE3a, BGE3b, and BGE3c and the sixth gate electrodes GE6a, GE6b, and GE6c through contact holes. Accordingly, the fourth gate signal line GSL4 may transmit the third gate signal to the third back gate electrodes BGE3a, BGE3b, and BGE3c and the sixth gate electrodes GE6a, GE6b, and GE6c. In addition, the fourth gate signal line GSL4 may electrically connect the third back gate electrodes BGE3a, BGE3b, and BGE3c and the corresponding sixth gate electrodes GE6a, GE6b, and GE6c.

The fifth gate signal line GSL5 may extend in the first direction DR1. The fifth gate signal line GSL5 may receive a second gate signal (e.g., GC in FIG. 3). The fifth gate signal line GSL5 may be connected to the second back gate electrodes BGE2a, BGE2b, and BGE2c and the fifth gate electrodes GE5a, GE5b, and GE5c through contact holes. Accordingly, the fifth gate signal line GSL5 may transmit the second gate signal to the second back gate electrodes BGE2a, BGE2b, and BGE2c and the fifth gate electrodes GE5a, GE5b, and GE5c. In addition, the fifth gate signal line GSL5 may electrically connect the second back gate electrodes BGE2a, BGE2b, and BGE2c and the corresponding fifth gate electrodes GE5a, GE5b, and GE5c.

The lower anode connection patterns LAPa, LAPb, and LAPc may be disposed in the first, second, and third pixel circuit areas PCA1, PCA2, and PCA3, respectively. In each of the first, second, and third pixel circuit areas PCA1, PCA2, and PCA3, the lower anode connection patterns LAPa, LAPb, and LAPc may be connected to the corresponding lower anode patterns ACP1a, ACP1b, and ACP1c through contact holes, respectively. Accordingly, the lower anode connection patterns LAPa, LAPb, and LAPc may be electrically connected to the third portions P3a, P3b, and P3c and the fourth portions P4a, P4b, and P4c of the corresponding lower anode patterns ACP1a, ACP1b, and ACP1c, respectively.

For example, the first data conductive layer DAT1 may include a metal, an alloy, a metal nitride, a conductive metal oxide, a transparent conductive material, and other conductive materials. These materials may be used alone or in combination with each other.

In the circuit layer CL, each routing line and connection pattern may transmit a corresponding electrical signal or voltage to a set of transistors or capacitive components within the pixel circuit. For example, the data voltage VDATA may be supplied via the data connection patterns DCPa, DCPb, and DCPc to the first upper active patterns ACP2a, ACP2b, and ACP2c. The initialization voltage VINT may be delivered through the initialization connection pattern ICP and the initialization voltage line IVL to the gate connection pattern GCP and to the second upper active patterns ACP3a, ACP3b, and ACP3c. The reference voltage VREF may be supplied through the first reference voltage line RVL1 to the first upper active patterns ACP2a, ACP2b, and ACP2c. The emission control signal EM1 may be transmitted through the second emission control line EL2 to the second gate electrodes GE2a, GE2b, and GE2c, and the emission control signal EM2 may be transmitted through the first emission control line EL1 to the third gate electrodes GE3a to GE3b.

In an embodiment, the circuit layer CL may include multiple stacked active layers, each corresponding to different sets of thin-film transistors. The lower active patterns ACP1a, ACP1b, and ACP1c may be formed in a lower active layer and may correspond to the first transistor T1, the sixth transistor T6, the seventh transistor T7, the eighth transistor T8, and the ninth transistor T9. The first upper active patterns ACP2a, ACP2b, and ACP2c may be disposed in an intermediate active layer and may serve as the active channels for the second transistor T2 and the fifth transistor T5. The second upper active patterns ACP3a, ACP3b, and ACP3c may be formed in a top active layer and may form the third transistor T3 and the fourth transistor T4. These multi-level active regions enable the vertical integration of driving and switching elements within each pixel circuit while minimizing horizontal area consumption.

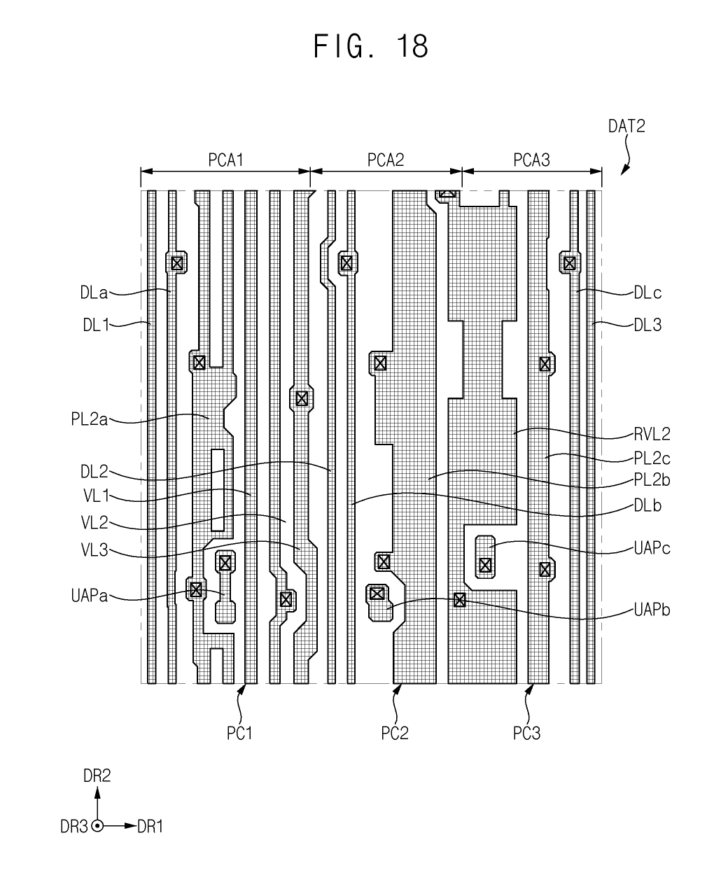

Referring further to FIGS. 18 and 19, the circuit layer CL may further include a second data conductive layer DAT2 disposed on the first data conductive layer DAT1. For example, a sixth insulating layer IL6 may be disposed on the first data conductive layer DAT1, and the second data conductive layer DAT2 may be disposed on the sixth insulating layer IL6. For example, the sixth insulating layer IL6 may include an organic material such as phenol resin, acrylic resin, polyimide resin, polyamide resin, siloxane resin, epoxy resin, and other insulating materials. These materials may be used alone or in combination with each other (see FIG. 20). The sixth insulating layer IL6 may electrically insulate the first data conductive layer DAT1 and the second data conductive layer DAT2.

The second data conductive layer DAT2 may include data lines DLa, DLb, and DLc, first data lines DL1, second data lines DL2, and third data lines DL3, first voltage lines VL1, second voltage lines VL2, and third voltage lines VL3, second power lines PL2a, PL2b, and PL2c, a second reference voltage line RVL2, and upper anode connection patterns UAPa, UAPb, and UAPc spaced apart from each other.

The data lines DLa, DLb, and DLc, the first data lines DL1, the second data lines DL2, and the third data lines DL3, the first voltage lines VL1, the second voltage lines VL2, and the third voltage lines VL3, the second power lines PL2a, PL2b, and PL2c, the second reference voltage line RVL2, and the upper anode connection patterns UAPa, UAPb, and UAPc may be disposed in the same layer. For example, the data lines DLa, DLb, and DLc, the first, second, and third data lines DL1, DL2, and DL3, the first, second, and third voltage lines VL1, VL2, and VL3, the second power lines PL2a, PL2b, and PL2c, the second reference voltage line RVL2, and the upper anode connection patterns UAPa, UAPb, and UAPc may include the same material and may be formed through the same process.

The data lines DLa, DLb, and DLc may be disposed in the first, second, and third pixel circuit areas PCA1, PCA2, and PCA3, respectively. The data lines DLa, DLb, and DLc may extend in the second direction DR2. The data lines DLa, DLb, and DLc may receive a data voltage (e.g., VDATA in FIG. 3). In each of the first, second, and third pixel circuit areas PCA1, PCA2, and PCA3, the data lines DLa, DLb, and DLc may be connected to the corresponding data connection patterns DCPa, DCPb, and DCPc through contact holes. Accordingly, the data voltage applied to the data lines DLa, DLb, and DLc may be transmitted to the corresponding first upper active patterns ACP2a, ACP2b, and ACP2c through the data connection patterns DCPa, DCPb, and DCPc.

The first, second, and third data lines DL1, DL2, and DL3 may be disposed in the first, second, and third pixel circuit areas PCA1, PCA2, and PCA3, respectively. The first, second, and third data lines DL1, DL2, and DL3 may extend in the second direction DR2, respectively. The first, second, and third data lines DL1, DL2, and DL3 may receive the data voltage. The first data line DL1 may transmit the data voltage to another pixel driving part adjacent to the first pixel driving part PC1 in the second direction DR2. The second data line DL2 may transmit the data voltage to another pixel driving part adjacent to the second pixel driving part PC2 in the second direction DR2. The third data line DL3 may transmit the data voltage to another pixel driving part adjacent to the third pixel driving part PC3 in the second direction DR2.

In an embodiment, the data lines DLa, DLb, and DLc and the first, second, and third data lines DL1, DL2, and DL3 might not overlap the power patterns PPa and PPb in the plan view. Accordingly, formation of parasitic capacitance between each of the data lines DLa, DLb, and DLc and each of the first, second, and third data lines DL1, DL2, DL3, and each of the power patterns PPa and PPb may be minimized or reduced (see FIG. 20).

In an embodiment, each of the data lines DLa, DLb, and DLc and the first, second, and third data lines DL1, DL2, and DL3 may at least partially overlap the first power line PL1 in the plan view (see FIG. 20).

The first voltage line VL1 may extend in the second direction DR2. For example, the first voltage line VL1 may receive an anode initialization voltage (e.g., VAINT in FIG. 3). In some cases, the first voltage line VL1 may be electrically connected to the second anode initialization voltage line AIL2 to transmit the anode initialization voltage to the second anode initialization voltage line AIL2. Alternatively, the first voltage line VL1 may receive a common voltage (e.g., ELVSS in FIG. 3). In some cases, the first voltage line VL1 may be electrically connected to a common electrode (e.g., CE in FIG. 4).

The second voltage line VL2 may extend in the second direction DR2. For example, the second voltage line VL2 may receive the anode initialization voltage (e.g., VAINT in FIG. 3). In some cases, the second voltage line VL2 may be connected to the transmission pattern TP through a contact hole, and the anode initialization voltage applied to the second voltage line VL2 may be transmitted to the first anode initialization voltage line AIL1 through the transmission pattern TP. In some cases, the second voltage line VL2 may receive the common voltage. In some cases, the second voltage line VL2 might not be connected to the transmission pattern TP, and may be electrically connected to the common electrode.

The third voltage line VL3 may extend in the second direction DR2. For example, the third voltage line VL3 may receive an initialization voltage (e.g., VINT in FIG. 3). In some cases, the third voltage line VL3 may be connected to the initialization connection pattern ICP through a contact hole, and the initialization voltage applied to the third voltage line VL3 may be transmitted to the initialization voltage line IVL through the initialization connection pattern ICP and the gate connection pattern GCP.

The second power lines PL2a, PL2b, and PL2c may be disposed in the first, second, and third pixel circuit areas PCA1, PCA2, and PCA3, respectively. The second power lines PL2a, PL2b, and PL2c may extend in the second direction DR2, respectively. The second power lines PL2a, PL2b, and PL2c may receive a driving voltage (e.g., ELVDD in FIG. 3). In each of the first, second, and third pixel circuit areas PCA1, PCA2, and PCA3, the second power lines PL2a, PL2b, and PL2c may be connected to the corresponding power connection patterns PCPa, PCPb, and PCPc and the first power line PL1 through contact holes, respectively. Accordingly, the driving voltage applied to the second power lines PL2a, PL2b, and PL2c may be transmitted to the second portions P2a, P2b, and P2c of the corresponding lower active patterns ACP1a, ACP1b, and ACP1c through the power connection patterns PCPa, PCPb, and PCPc, and may be transmitted to the power patterns PPa and PPb and the lower metal pattern BMP through the first power line PL1.

The second reference voltage line RVL2 may extend in the second direction DR2. The second reference voltage line RVL2 may receive a reference voltage (e.g., VREF in FIG. 3). The second reference voltage line RVL2 may be located between the second power lines PL2b and PL2c in the plan view. The second reference voltage line RVL2 may be connected to the first reference voltage line RVL1 through a contact hole. Accordingly, the reference voltage applied to the second reference voltage line RVL2 may be transmitted to the first upper active patterns ACP2a, ACP2b, and ACP2c through the first reference voltage line RVL1.

The upper anode connection patterns UAPa, UAPb, and UAPc may be disposed in the first, second, and third pixel circuit areas PCA1, PCA2, and PCA3, respectively. In each of the first, second, and third pixel circuit areas PCA1, PCA2, and PCA3, the upper anode connection patterns UAPa, UAPb, and UAPc may be connected to corresponding lower anode connection patterns LAPa, LAPb, and LAPc through contact holes, respectively. In addition, the upper anode connection patterns UAPa, UAPb, and UAPc may be connected to a pixel electrode (e.g., PE in FIG. 4) through contact holes, respectively. In some cases, the pixel electrode may be electrically connected to the third portions P3a, P3b, and P3c and the fourth portions P4a, P4b, and P4c of the corresponding lower active patterns ACP1a, ACP1b, and ACP1c through the corresponding upper anode connection patterns UAPa, UAPb, and UAPc and the corresponding lower anode connection patterns LAPa, LAPb, and LAPc. Accordingly, a light-emitting element (e.g., LED in FIGS. 3 and 4) including the pixel electrode and the corresponding first, second, and third pixel driving circuit parts PC1, PC2, and PC3 may be electrically connected.

For example, the second data conductive layer DAT2 may include a metal, an alloy, a metal nitride, a conductive metal oxide, a transparent conductive material, and the like. These materials may be used alone or in combination with each other.

Referring further to FIG. 20, a seventh insulating layer IL7 may be disposed on the second data conductive layer DAT2. The seventh insulating layer IL7 may include an organic material such as phenol resin, acrylic resin, polyimide resin, polyamide resin, siloxane resin, epoxy resin, and other organic materials. These materials may be used alone or in combination with each other.

In some embodiments, the substrate SUB may form the base of the display panel. A lower metal pattern BMP may be disposed on the substrate SUB. The lower metal pattern BMP may include a power line region configured to receive a driving voltage (e.g., ELVDD) and may serve as a back gate electrode for one or more transistors. A buffer layer BUF is disposed on the substrate SUB and the lower metal pattern BMP. The buffer layer BUF covers an upper surface and side surfaces of the lower metal pattern BMP, providing electrical insulation and planarization.

A first insulating layer IL1 is disposed on the buffer layer BUF. The conductive patterns CPa, CPb, and CPc are disposed on the first insulating layer IL1. A second insulating layer IL2 is disposed on the conductive patterns CPa, CPb, and CPc and the first insulating layer IL1. The second insulating layer IL2 electrically insulates the conductive patterns from upper gate or signal layers.

A third insulating layer IL3 is disposed on the second insulating layer IL2, and a second active layer ACT2 may be disposed on third insulating layer IL3. The power patterns PPa and PPb may be disposed on the third insulating layer IL3. A fourth insulating layer IL4 is disposed on IL3, and a third gate conductive layer GAT3 may be formed on the fourth insulating layer IL4. A fifth insulating layer IL5 is disposed on the third gate conductive layer GAT3, and a first data conductive layer DAT1 is formed on IL5. The first data conductive layer DAT1 may include first connection patterns CNP1a, CNP1b, and CNP1c, which vertically interconnect active patterns and electrode layers in each pixel circuit area PCA1, PCA2, and PCA3.

A sixth insulating layer IL6 may be disposed on the first data conductive layer DAT1 (which may include the connection patterns), and a second data conductive layer DAT2 may be disposed on the sixth insulating layer IL6. The second data conductive layer DAT2 may include data lines DL1 to DL3, DLa to DLc, voltage lines VL1 to VL3, power lines PL2a to PL2c, and reference voltage line RVL2, and others connection lines. These connection lines deliver driving and control signals (e.g., VDATA, VINT, VAINT, VREF) to each pixel circuit area PCA1, PCA2, and PCA3.

Additionally, a seventh insulating layer IL7 may be disposed on and covering the second data conductive layer DAT2. The seventh insulating layer IL7 may include an organic insulating material such as phenol resin, acrylic resin, polyimide resin, polyamide resin, siloxane resin, epoxy resin, or combinations thereof, and may serve as a planarization and/or encapsulation layer.

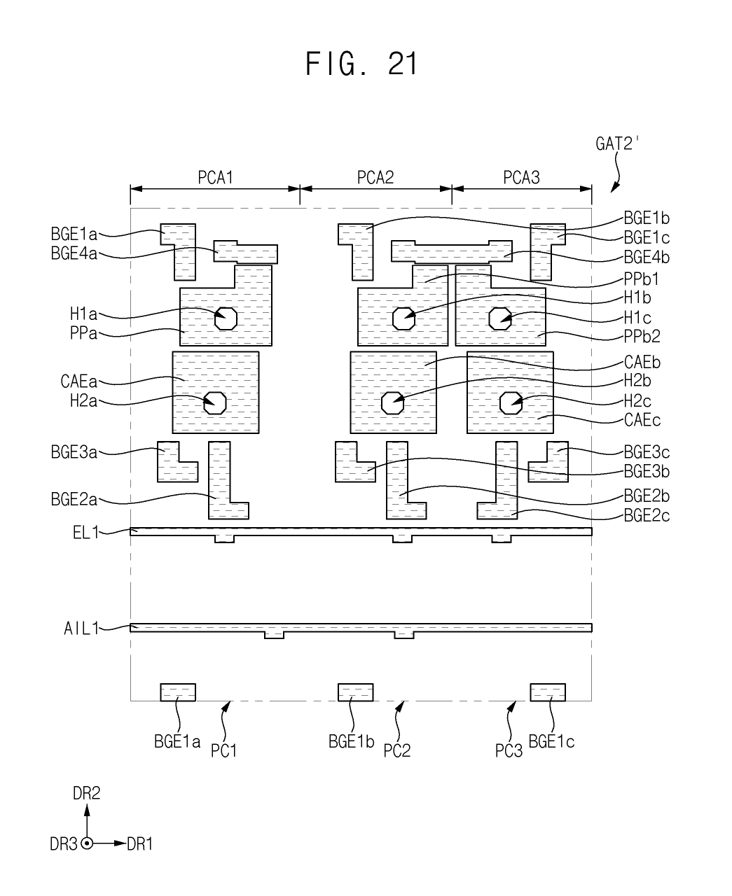

FIG. 21 is a layout view illustrating an example of a second gate conductive layer of FIG. 10. A second gate conductive layer GAT2′ described with reference to FIG. 21 may be substantially the same as or similar to the second gate conductive layer GAT2 described with reference to FIG. 10, except for the shapes of the power patterns PPa, PPb, and PPc. Hereinafter, descriptions on the differences may be described.

Referring to FIG. 21, the second gate conductive layer GAT2′ may include first back gate electrodes BGE1a, BGE1b, and BGE1c, second back gate electrodes BGE2a, BGE2b, and BGE2c, third back gate electrodes BGE3a, BGE3b, and BGE3c, fourth back gate electrodes BGE4a and BGE4b, capacitor electrodes CAEa, CAEb, and CAEc, power patterns PPa, PPb1, and PPb2, a first emission control line EL1, and a first anode initialization voltage line AIL1.

The power patterns PPa, PPb1, and PPb2 may be disposed in the first, second, and third pixel circuit areas PCA1, PCA2, and PCA3, respectively. The power patterns PPa, PPb1, and PPb2 may receive a driving voltage (e.g., ELVDD in FIG. 3). In an embodiment, the power patterns PPa, PPb1, and PPb2 may be disposed to be spaced apart from each other. For example, in the second and third pixel circuit areas PCA2 and PCA3, the power patterns PPb1 and PPb2 may be independently disposed. The power patterns PPa, PPb1, and PPb2 may be referred to as a first power pattern, a second power pattern, and a third power pattern, respectively.

In the first pixel circuit area PCA1, the power pattern PPa may at least partially overlap a conductive pattern (e.g., CPa in FIG. 9) in the plan view. Accordingly, a first capacitor (e.g., C1 in FIG. 11) may include the power pattern PPa together with the conductive pattern. In the second pixel circuit area PCA2, the power pattern PPb1 may at least partially overlap a conductive pattern (e.g., CPb in FIG. 9) in the plan view. Accordingly, a first capacitor (e.g., C1 in FIG. 11) may include the power pattern PPb1 together with the conductive pattern. In the third pixel circuit area PCA3, the power pattern PPb2 may at least partially overlap with a conductive pattern (e.g., CPc in FIG. 9) in the plan view. Accordingly, a first capacitor (e.g., C1 in FIG. 11) may include the power pattern PPb2 together with the conductive pattern. These capacitors may function as storage capacitors for maintaining a gate voltage or data voltage applied to the pixel driving circuit.

The corresponding first holes H1a, H1b, and H1c may be formed in the power patterns PPa, PPb1, and PPb2, respectively. In each of the first, second, and third pixel circuit areas PCA1, PCA2, and PCA3, the first holes H1a, H1b, and H1c may expose at least a portion of the corresponding conductive patterns (e.g., CPa, CPb, and CPc in FIG. 9), respectively.

Referring again to FIGS. 1 to 21, the display device DD according to embodiments of the present disclosure may include the conductive patterns CPa, CPb, and CPc disposed in each of first, second, and third pixel circuit areas PCA1, PCA2, and PCA3, and the corresponding power patterns PPa, PPb, PPb1, and PPb2 form the first capacitor C1 together with the conductive patterns CPa, CPb, and CPc in each of the first, second, and third pixel circuit areas PCA1, PCA2, and PCA3. The driving voltage may be applied to the power patterns PPa, PPb, PPb1, and PPb2. In addition, the data lines DL1, DL2, DL3, DLa, DLb, and DLc which receives the data voltage VDATA might not overlap the power patterns PPa, PPb, PPb1, and PPb2 in the plan view. Accordingly, the formation of parasitic capacitor between each of the data lines DL1, DL2, DL3, DLa, DLb, and DLc and each of the power patterns PPa, PPb, PPb1, and PPb2 may be minimized or reduced. Accordingly, the crosstalk phenomenon caused by the formation of the parasitic capacitance may be prevented or reduced.

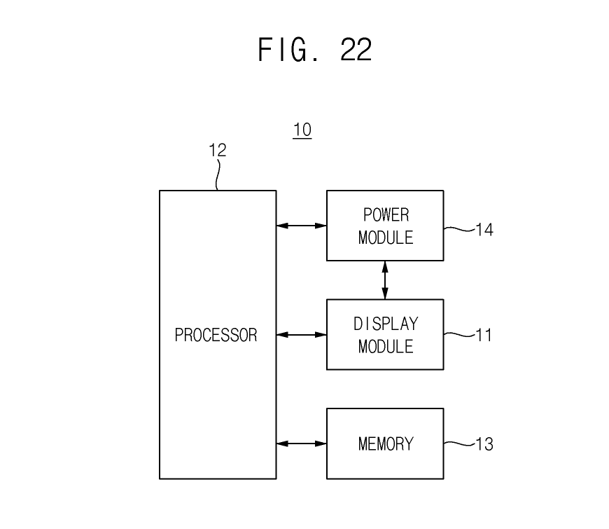

FIG. 22 is a block diagram illustrating an electronic device according to embodiments of the present disclosure.

Referring to FIG. 22, an electronic device 10 may include a display module 11, a processor 12, a memory 13, and a power module 14. A display device (e.g., the display device DD of FIGS. 1 and 2) may be applied to various electronic devices. The electronic device 10 may include the display device described above, and may further include a module or device having additional functions in addition to the display device.

The processor 12 may include at least one of a central processing unit (CPU), an application processor (AP), a graphic processing unit (GPU), a communication processor (CP), an image signal processor (ISP), and a controller. The processor 12 may also include a digital signal processor (DSP), a central processing unit (CPU), a microcontroller, an application-specific integrated circuit (ASIC), a field programmable gate array (FPGA), a programmable logic device, a discrete gate or transistor logic component, a discrete hardware component, or a combination thereof. In some embodiments, the processor 12 may include a main processor and an auxiliary controller. The controller may include an interface conversion circuit and a timing control circuit for formatting and synchronizing image data for output to the display module 11.

The memory 13 may store data information for the operation of the processor 12 or the display module 11. If the processor 12 executes the application stored in the memory 13, an input image data (e.g., IDAT in FIG. 2) and/or a control signal (e.g., CTRL in FIG. 2) may be transmitted to the display module 11, and the display module 11 may process the received signal and output image information through a display screen. In an embodiment, the memory 13 may store one or more application programs such as a camera application, video streaming software, GPS, or AR/VR functionality, along with corresponding user interface settings or system data. These applications may be activated via user input through a touch screen or gesture recognition sensor.

The power module 14 may include a power supply module, such as a power adapter or a battery device, and a power conversion module which converts the power supplied by the power supply module to generate power required for the operation of the electronic device 10. The power module 14 may include a rechargeable battery (or battery) and a power management integrated circuit (PMIC) that supplies power to the processor 12, the display module 11, and other components of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

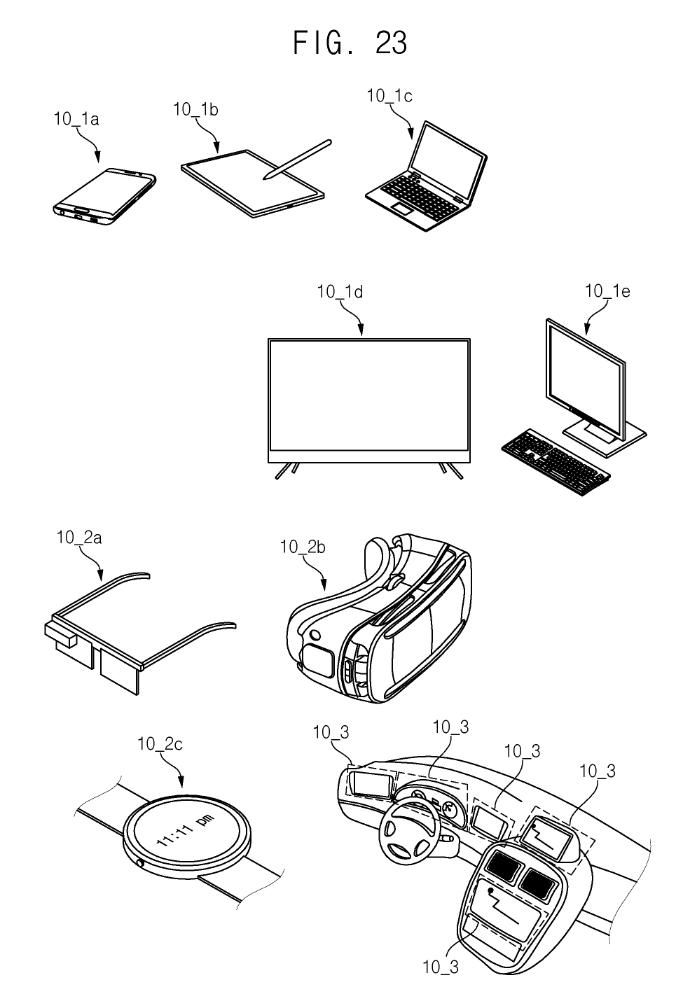

FIG. 23 is a schematic view showing an electronic device according to various embodiments.

Referring to FIGS. 22 and 23, various electronic devices 10 including the display devices described above may include image display electronic devices such as a smartphone 10_1a, a tablet PC 100_1b, a laptop 10_1c, a TV 10_1d, and a desktop monitor 10_1e, and wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or other electronic devices that may include a display device.

As described above, while the present disclosure has been explained with reference to exemplary embodiments, it will be understood by those of ordinary skill in the art that various modifications and changes can be made thereto without departing from the spirit and scope of the inventive concept as recited in the following claims.

The present disclosure may be applied to various display devices which can be equipped with a display device. For example, the present disclosure may be applied to high-resolution smartphones, mobile phones, smart pads, smart watches, tablets, personal computers (PCs), vehicle navigation systems, televisions, computer monitors, and notebook computers.

What is claimed is:

1. A display device, comprising:
a substrate having an upper surface including a first substrate area adjacent to a second substrate area;
a first pixel driving circuit and a second pixel driving circuit overlapping the first and second substrate areas, respectively;
a first conductive structure overlapping the first substrate area;
a second conductive structure disposed in a same layer as the first conductive structure and overlapping the second substrate area;
a first power conductor overlapping each of the first conductive structure and the first substrate area, wherein the first power conductor and the first conductive structure are opposite electrodes of a first storage capacitor of the first pixel driving circuit;
a second power conductor disposed in a same layer as, and spaced from, the first power conductor, and overlapping each of the second substrate area and the second conductive structure, wherein the second power conductor and the second conductive structure are opposite electrodes of a second storage capacitor of the second pixel driving circuit;
a power line overlapping and connected to each of the first and second power conductors, wherein the power line is configured to receive a driving voltage;
a first light-emitting element electrically connected to the first pixel driving circuit and configured to emit light having a first color; and
a second light-emitting element electrically connected to the second pixel driving circuit and configured to emit light having a second color different from the first color.

2. The display device of claim 1, wherein:
the first power conductor includes a first hole exposing at least a portion of the first conductive structure, and
the second power conductor includes a second hole exposing at least a portion of the second conductive structure.

3. The display device of claim 1, further comprising:
a first data line disposed on the power line in the first substrate area; and
a second data line disposed on the power line in the second substrate area,
wherein the first data line and the second data line do not overlap the first power conductor and the second power conductor.

4. The display device of claim 3, wherein:
the first data line and the second data line each at least partially overlap the power line.

5. The display device of claim 3, wherein:
the substrate further includes a third substrate area adjacent to the second substrate area,
wherein the display device further includes:
a third pixel driving circuit overlapping the third substrate area;
a third conductive structure disposed on the substrate in the same layer as the first conductive structure in the third substrate area; and
a third power conductor disposed on the third conductive structure in the same layer as the first power conductor in the third substrate area, at least partially overlapping the third conductive structure, and spaced apart from the first power conductor, wherein the third power conductor and the third conductive structure are parts of a third storage capacitor of the third pixel driving circuit, and
wherein the power line is connected to the third power conductor.

6. The display device of claim 5, further comprising:
a third data line disposed on the power line in the third substrate area,
wherein the first data line, the second data line, and the third data line do not overlap the first power conductor, the second power conductor, and the third power conductor, respectively.

7. The display device of claim 5, wherein:
the third power conductor is integrally formed with the second power conductor.

8. The display device of claim 5, wherein:
the third power conductor is spaced apart from the second power conductor.

9. The display device of claim 5, further comprising:
a third light-emitting element electrically connected to the third pixel driving circuit part, wherein the third light-emitting element is configured to emit light having a third color different from the first color and the second color.

10. The display device of claim 5, wherein:
the third power conductor includes a third hole exposing at least a portion of the third conductive structure.

11. The display device of claim 3, further comprising:
an additional power line disposed in a same layer as the first data line and the second data line and connected to the power line.

12. The display device of claim 1, further comprising:
a lower metal pattern disposed between the substrate and the first conductive structure and the second conductive structure, and at least partially overlapping the first conductive structure and the second conductive structure,
wherein the lower metal pattern is electrically connected to the power line.

13. The display device of claim 1, further comprising:
a plurality of lower active patterns, wherein a first one of the plurality of lower active patterns is disposed in the first substrate area between the substrate and the first conductive structure, and a second one of the plurality of lower active patterns is disposed in the second substrate area and between the substrate and the second conductive structure; and
a plurality of first gate electrodes, wherein a first one of the plurality of first gate electrodes is disposed in the first substrate area on the first one, and a second one of the plurality of first gate electrodes is disposed in the second substrate area on the second one , each of the plurality of first gate electrodes at least partially overlapping a corresponding lower active pattern, wherein each of the plurality of first gate electrodes and each of the plurality of lower active patterns are parts of a driving transistor of each of the first pixel driving circuit and the second pixel driving circuit, respectively, wherein the plurality of lower active patterns includes a silicon semiconductor.

14. The display device of claim 13, further comprising:
a plurality of upper active patterns, wherein each of the plurality of upper active patterns is disposed in the first substrate area and the second substrate area on the first power conductor and the second power conductor, respectively; and
a plurality of second gate electrodes, wherein a first one of the plurality of second gate electrodes is disposed in the first substrate area on a corresponding upper active pattern, and a second one of the plurality of second gate electrodes is disposed on another corresponding upper active pattern in the second substrate area, each of the plurality of second gate electrodes at least partially overlapping each of the plurality of upper active patterns, wherein each of the plurality of second gate electrodes and each of the plurality of upper active patterns are parts of a switching transistor of each of the first pixel driving circuit and the second pixel driving circuit, respectively,
wherein the plurality of upper active patterns includes a metal oxide semiconductor.

15. An electronic device, comprising:
a display device; and
a processor for controlling the display device by transmitting input image data and control signal to the display device,
wherein the display device includes:
a substrate having an upper surface including a first substrate area adjacent to a second substrate area;
a first pixel driving circuit and a second pixel driving circuit overlapping the first and second substrate areas, respectively;
a first conductive structure overlapping the first substrate area;
a second conductive structure disposed in a same layer as the first conductive structure and overlapping the second substrate area;
a first power conductor overlapping each of the first conductive structure and the first substrate area, wherein the first power conductor and the first conductive structure are opposite electrodes of a first storage capacitor of the first pixel driving circuit;
a second power conductor disposed in a same layer as, and spaced from, the first power conductor, and overlapping each of the second substrate area and the second conductive structure, wherein the second power conductor and the second conductive structure are opposite electrodes of a second storage capacitor of the second pixel driving circuit;
a power line overlapping and connected to each of the first and second power conductors, wherein the power line is configured to receive a driving voltage;
a first light-emitting element electrically connected to the first pixel driving circuit and configured to emit light having a first color; and
a second light-emitting element electrically connected to the second pixel driving circuit and configured to emit light having a second color different from the first color.

16. The electronic device of claim 15, wherein:
the first power conductor includes a first hole exposing at least a portion of the first conductive structure, and
the second power conductor includes a second hole exposing at least a portion of the second conductive structure.

17. The electronic device of claim 15, wherein the display device further includes:
a first data line disposed in the first substrate area on the power line; and
a second data line disposed in the second substrate area on the power line,
wherein the first data line and the second data line do not overlap the first power conductor and the second power conductor.

18. The electronic device of claim 17, wherein:
the first data line and the second data line each at least partially overlap the power line.

19. An electronic device, comprises:
a display device; and
a processor for controlling the display device by transmitting input image data and control signal to the display device,
wherein the display device includes:
a substrate having an upper surface including a first substrate area adjacent to a second substrate area and a third substrate area adjacent to the second substrate area;
a first pixel driving circuit, a second pixel driving circuit, and a third pixel driving circuit overlapping the first, second, and third substrate areas, respectively;
a first conductive structure overlapping the first substrate area;
a second conductive structure disposed in a same layer as the first conductive structure and overlapping the second substrate area;
a third conductive structure disposed on the substrate in the same layer as the first conductive structure in the third substrate area;
a first power conductor overlapping each of the first conductive structure and the first substrate area, wherein the first power conductor and the first conductive structure are opposite electrodes of a first storage capacitor of the first pixel driving circuit;
a second power conductor disposed in a same layer as, and spaced from, the first power conductor, and overlapping each of the second substrate area and the second conductive structure, wherein the second power conductor and the second conductive structure are opposite electrodes of a second storage capacitor of the second pixel driving circuit;
a third power conductor disposed on the third conductive structure in the same layer as the first power conductor in the third substrate area, at least partially overlapping the third conductive structure, and spaced from the first power conductor, wherein the third power conductor and the third conductive structure are opposite electrodes of a third storage capacitor of the third pixel driving circuit;
a power line overlapping and connected to each of the first and second power conductors, wherein the power line is configured to receive a driving voltage;
a first light-emitting element electrically connected to the first pixel driving circuit and configured to emit light having a first color; and
a second light-emitting element electrically connected to the second pixel driving circuit and configured to emit light having a second color different from the first color; and
a third light-emitting element electrically connected to the third pixel driving circuit, wherein the third light-emitting element is configured to emit light having a third color different from the first color and the second color,
wherein the power line is connected to the third power conductor.

20. The electronic device of claim 19, wherein the display device further includes:
a first data line disposed in the first substrate area on the power line;
a second data line disposed in the second substrate area on the power line; and
a third data line disposed in the third substrate area on the power line, and
wherein the first data line, the second data line, and the third data line do not overlap the first power conductor, the second power conductor, the third power conductor, respectively.
